(19) United States
(12) Patent Application Publication
(10) Pub. No.: US 2007/0297878 A1
(43) Pub. Date: Dec. 27, 2007

(54) SUBSTRATE TRANSFER APPARATUS FEATURING LOWER AND UPPER PNEUMATIC SUCKER ARMS, AND SUBSTRATE TRANSFER METHOD CARRIED OU IN SUCH SUBSTRATE TRANSFER APPARATUS

(75) Inventor: Yasuyuki Masutani, Shiga (JP)

Correspondence Address: YOUNG & THOMPSON, 745 SOUTH 23RD STREET, 2ND FLOOR, ARLINGTON, VA, 22202, US

(73) Assignee: NEC Electronics Corporation, Kanagawa (JP)

(21) Appl. No.: 11/765,532

(22) Filed: Jun. 20, 2007

(30) Foreign Application Priority Data
Jun. 20, 2006 (JP) 2006-169979

(51) Int. Cl. H01L 21/67

(52) U.S. Cl. 414/222.02; 414/806

(57) ABSTRACT

In a substrate transfer apparatus that pneumatically holds and transfers a substrate having first and second surfaces, a first pneumatic sucker arm has at least two first suction ports for pneumatically sucking the first surface of the substrate, and a second pneumatic sucker arm has at least two second suction ports for pneumatically sucking the second surface of the substrate. First and second drive mechanisms vertically move the first and second pneumatic sucker arms toward the respective first and second surfaces of the substrate, with the at least two first suction ports and the at least two second suction ports being directed to the respective first and surfaces of the substrate. The vertical movement of the first pneumatic sucker arm is stopped when any one of sucking pressures generated in the first suction ports is lowered to a predetermined low pressure, and the vertical movement of the second pneumatic sucker arm is stopped when any one of sucking pressures generated in the second suction ports is lowered to the predetermined low pressure.

### BACKGROUND OF THE INVENTION

1. Field of the Invention

The present invention relates to a substrate transfer apparatus which is used to transfer a substrate from one location to another location in a semiconductor device manufacturing line, and also relates to a substrate transfer method which is carried out in such a substrate transfer apparatus.

2. Description of the Related Art

In a semiconductor device manufacturing line, it is necessary to transfer substrates such as a semiconductor wafer, a wiring board or the like from one location to another location.

For example, JP-H07-147317 A discloses a substrate transfer apparatus which is used to transfer a semiconductor wafer from one location to another location. In operation of the substrate transfer apparatus, a plurality of semiconductor wafers must be unloaded from and loaded into a wafer cassette or wafer container. The substrate transfer apparatus includes a pneumatic sucker arm having suction ports for pneumatically sucking a back surface of the semiconductor wafer. Namely, by pneumatically sucking and holding the semiconductor wafer using the pneumatic sucker arm, the unloading of the semiconductor wafer from the wafer container and the loading of the semiconductor wafer into the wafer container are carried out. This will be explained later in detail.

### SUMMARY OF THE INVENTION

It has now been discovered that the above-mentioned prior art substrate transfer apparatus has a problem to be solved as will be mentioned in detail hereinafter.

Recently, the diameter of semiconductor wafers become larger in order to manufacture a large amount of semiconductor device chips or integrated circuit chips at low cost. On the other hand, with the recent advance in scaling and integration of semiconductor devices, a thickness of the semiconductor wafer has become thinner.

During the manufacture of semiconductor devices, the semiconductor wafers are subjected to thermal stresses or the like, resulting in warpage of the semiconductor wafer. The warpage of the semiconductor wafer is amplified by increasing the wafer diameter and decreasing the wafer thickness, so that it is very difficult or impossible to properly handle the semiconductor wafer by the prior art substrate transfer apparatus, as will be stated in detail hereinafter.

In accordance with a first aspect of the present invention, there is provided a substrate transfer apparatus that pneumatically holds and transfers a substrate having first and second surfaces. The substrate transfer apparatus includes a first pneumatic sucker arm having at least two first suction ports for pneumatically sucking the first surface of the substrate, a first drive mechanism that vertically moves the first pneumatic sucker arm toward the first surface of the substrate, with the at least two first suction ports being directed to the first surface of the substrate, and a plurality of first pressure sensors that detect respective sucking pressures generated in the at least two first suction ports. The substrate transfer apparatus also includes a second pneumatic sucker arm having at least two second suction ports for pneumatically sucking the second surface of the substrate, a second drive mechanism that vertically moves the second pneumatic sucker arm toward the second surface of the substrate, with the at least two second suction ports being directed to the second surface of the substrate, and a plurality of second pressure sensors that detect respective sucking pressures generated in the at least two second suction ports. The substrate transfer apparatus further includes a control circuit that controls the vertical movement of the first pneumatic sucker arm in accordance with the respective sucking pressures detected by the first pressure and the vertical movement of the second pneumatic sucker arm in accordance with the respective sucking pressures detected by the second pressure sensors.

In the substrate transfer apparatus, the control circuit may stop the vertical movement of the first pneumatic sucker arm when a sucking pressure in any one of the at least two first suction ports is detected as a predetermined low pressure by a corresponding one of the first pressure sensors, and may stop the vertical movement of the second pneumatic sucker arm when a sucking pressure in any one of the at least two second suction ports is detected as a predetermined low pressure by a corresponding one of the second pressure sensors.

The control circuit may stop the movement of the second pneumatic sucker arm when the sucking pressures in the at least two first suction ports are lowered to a predetermined low pressure.

When the substrate is defined as a semiconductor wafer, preferably, the at least two first suction ports are spaced apart from each other so as to be in contact with respective diametrical side edge areas on the first surface of the semiconductor wafer, and the at least two second suction ports are spaced apart from each other so as to be in contact with respective diametrical side edge areas on the second surface of the semiconductor wafer.

When the at least two first suction ports are defined as suction ports positioned at the endmost sides of the wafer, the first pneumatic sucker arm may further have an additional first suction port arranged between the endmost first suction ports. Similarly, when the at least two second suction ports are defined as suction ports positioned at the endmost sides of the wafer, the second pneumatic sucker arm may further have an additional first suction port arranged between the endmost first suction ports.

Further, when the substrate is defined as a semiconductor wafer, the second pneumatic sucker arm may have two projections in which the at least two suction ports are formed in the projections, the at least two suction ports being spaced apart from each other so as to be in contact with respective diametrical side edge areas on the second surface of the semiconductor wafer. In this case, preferably, the projections have a height which defines a sufficient space between the first and second pneumatic sucker arms to receive a maximum warped semiconductor wafer, without the second surface of the maximum warped semiconductor wafer being brought into contact with the second pneumatic sucker arm.

In accordance with a second aspect of the present invention, there is provided a method for transferring a substrate having first and second surfaces, which comprises: positioning a first pneumatic sucker arm having at least two first suction ports and a second pneumatic sucker arm having at least two second suction ports in place with respect to the substrate, so that the at least two first suction ports and the at least two second suction ports are directed to the respective first and second surfaces of the substrate; moving the first pneumatic sucker arm toward the first surface of the substrate; detecting respective first sucking pressures generated in the at least two first suction ports; stopping the movement of the first pneumatic sucker arm when it is detected that any one of the first sucking pressures is lowered to a predetermined low pressure; moving the second pneumatic sucker arm toward the second surface of the substrate; detecting respective second sucking pressures generated in the at least two second suction ports, and stopping the movement of the second pneumatic sucker arm when it is detected that any one of the second sucking pressures is lowered to the predetermined low pressure.

In accordance with a third aspect of the present invention, there is provided a method for transferring a substrate having first and second surfaces, which comprises: positioning a first pneumatic sucker arm having at least two first suction ports and a second pneumatic sucker arm having at least two second suction ports in place with respect to the substrate, so that the at least two first suction ports and the at least two second suction ports are directed to the respective first and second surfaces of the substrate; moving the first pneumatic sucker arm and the second pneumatic sucker arm toward the first and second surfaces of the substrate, respectively, detecting respective first sucking pressures generated in the at least two first suction ports and respective second sucking pressures generated in the at least two second suction ports, stopping the movement of the first pneumatic sucker arm when it is detected that any one of the first sucking pressures is lowered to a predetermined low pressure, and stopping the movement of the second pneumatic sucker arm when it is detected that any one of the second sucking pressures is lowered to the predetermined low pressure.

### BRIEF DESCRIPTION OF THE DRAWINGS

The present invention will be more clearly understood from the description set forth below, as compared with a prior art semiconductor wafer transfer apparatus, with reference to the accompanying drawings, wherein:

FIG. 1 is a schematic view of a prior art substrate transfer apparatus for transferring a substrate such as a semiconductor wafer;

FIG. 2 is a plan view; which is a cross-sectional view of a wafer container in and from which a semiconductor wafer is loaded and unloaded by a pneumatic sucker arm of the substrate transfer apparatus of FIG. 1;

FIGS. 3A and 3B are cross-sectional views taken along the III-III line of FIG. 2, with the wafer container being omitted to avoid complexity of illustration;

FIG. 4 is a schematic view of an embodiment of the substrate transfer apparatus for transferring a substrate such as a semiconductor wafer, according to the present invention;

FIG. 5A is a partial perspective view of a lower pneumatic sucker arm of the substrate transfer apparatus of FIG. 4;

FIG. 5B is a partial plan view of the lower pneumatic sucker arm of FIG. 5A;

FIG. 6A is a partial perspective view of an upper pneumatic sucker arm of the substrate transfer apparatus of FIG. 4;

FIG. 6B is a partial bottom view of the upper pneumatic sucker arm of FIG. 6A;

FIG. 7A is a longitudinally-sectional view of a wafer container in and from which a semiconductor wafer is loaded and unloaded by the lower and upper pneumatic sucker arms of the substrate transfer apparatus of FIG. 4;

FIG. 7B is a cross-sectional view taken along the B-B line of FIG. 7A;

FIGS. 8A, 8B and 8C are explanatory views which correspond to partially-enlarged views of FIG. 7A for explaining how to unload one of the semiconductor wafers from the wafer container by the lower and upper pneumatic sucker arms of the substrate transfer apparatus of FIG. 4;

FIGS. 9A, 9B, 9C and 9D are views, which correspond to FIG. 8C, illustrating representative examples of warpage of the semiconductor wafer, with the semiconductor container being omitted to avoid complexity of illustration;

FIG. 10 is a detailed block circuit block diagram of FIG. 4;

FIG. 11 is a flowchart of the wafer-unloading routine executed in a microcomputer of FIG. 10;

FIG. 12 is a detailed flowchart of a first example of the pressure-sensor monitoring routine of FIG. 11;

FIG. 13 is a detailed flowchart of a second pressure-sensor monitoring routine of FIG. 11;

FIG. 14 is a detailed flowchart of a second example of the pressure-sensor monitoring routine of FIG. 11;

FIG. 15 is another flowchart of the wafer-unloading routine of FIG. 11 executed in the microcomputer of FIG. 10;

FIG. 16 is a detailed flowchart of the pressure-sensor monitoring routine of FIG. 15;

FIG. 17 is a flowchart of the wafer-loading routine executed in the microcomputer of FIG. 10; and

FIGS. 18A and 18B are partially-enlarged views corresponding to FIGS. 8B and 8C, respectively, for explaining a second embodiment of the substrate transfer apparatus according to the present invention.

### DESCRIPTION OF THE PREFERRED EMBODIMENTS

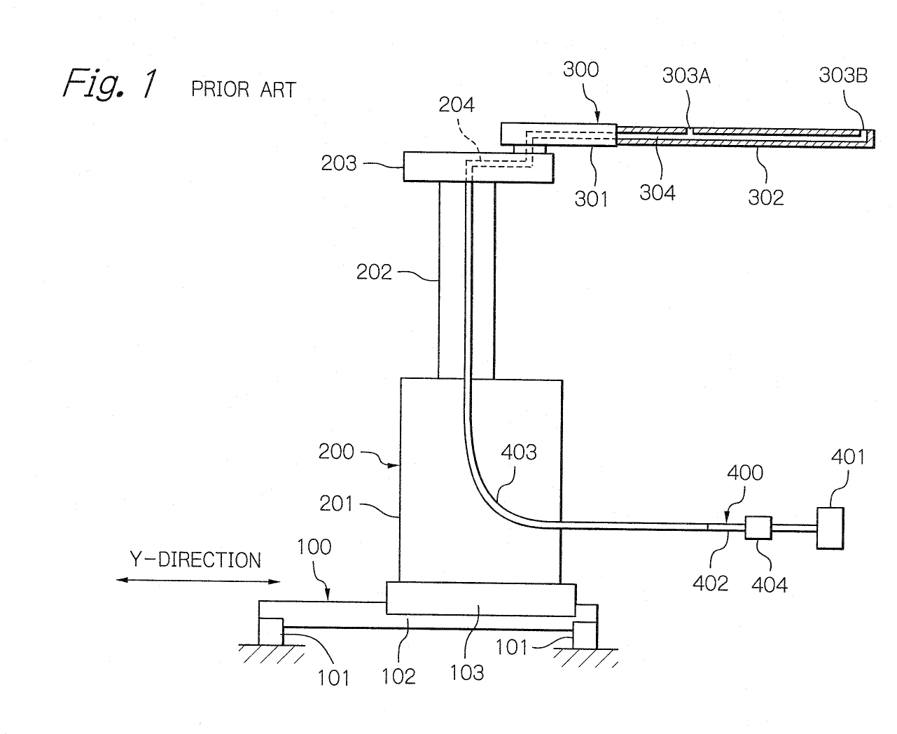

Before the description of embodiments of the present invention, for better understanding of the present invention, with reference to FIGS. 1 and 2 and FIGS. 3A and 3B, the prior art substrate transfer apparatus will be described below.

First, referring to FIG. 1 which is a schematic view of the prior art substrate transfer apparatus as disclosed in JP-H07-147317 A, the substrate transfer apparatus includes an X-Y table unit 100 which has a pair of guide rails 101 laid on a floor so as to be extended in an X-direction in parallel with the guide rails 101, a pair of guide rails 102 slidably provided on the pair of guide rails 101 and extended in a Y-direction perpendicular to the X-direction, and an X-Y table 103 slidably provided on the pair of guide rails 102. Note, in FIG. 1, only one of the guide rails 102 is visible.

Although not illustrated in FIG. 1, the X-Y table unit 100 is provided with a drive mechanism for moving the guide rails 102 along the guide rails 101, and a drive mechanism for moving the X-Y table 103 along the guide rails 102. Each of the drive mechanisms may be formed as a ball/screw mechanism for converting a rotational movement into a translational movement.

With the above-mentioned arrangement of the X-Y table unit 100, the X-Y table 103 can be suitably moved in the X-direction and/or the Y-direction.

The substrate transfer apparatus also includes a drive unit 200 provided on the X-Y table 103, and the drive unit 200 has a housing 201 securely mounted on the X-Y table 103, a movable column 202 provided in the housing 201 so as to be vertically moved, and a rest member 203 securely fixed on a top of the movable column 202 and having an air passage 204 formed therein.

Although not illustrated in FIG. 1, the drive unit 2 is provided with a drive mechanism for vertically moving the column 202. The drive mechanism may be formed as a rack/pinion mechanism for converting a rotational movement into a translational movement.

The substrate transfer apparatus further includes a pneumatic sucker arm 300 which is mounted on the rest member 203 to suck and hold a substrate such as a semiconductor wafer. The pneumatic sucker arm 300 includes a base portion 301 securely attached to the rest member 203, and a sucker portion 302 integrally extending therefrom. In short, the pneumatic sucker arm 300 is supported by the rest member 203 in a cantilever manner.

The sucker portion 302 of the pneumatic sucker arm 300 has two suction ports 303A and 303B which are formed in an upper face thereof so as to be aligned with each other along a central longitudinal axis of the sucker portion 302, and an air passage 304 is formed in both the base portion 301 and the sucker portion 302 so as to be in communication with the suction ports 303A and 303B, with the air passage 304 being in communication with the air passage 204 formed in the rest member 203.

The substrate transfer apparatus further includes a vacuum unit 400 associated with the pneumatic sucker arm 300. The vacuum unit 400 has a vacuum pump 401 suitably installed in place, a rigid pipe 402 connected to a suction port of the vacuum pump 401, and a flexible conduit 403 connected to the rigid pipe 402 at one end thereof, with the other end of the flexible conduit 403 being connected to the rest member 203 so as to be in communication with the air passage 204 formed in the rest member 203. The vacuum unit 400 also has a pressure sensor 404 incorporated in the rigid pipe 402 to thereby detect an internal pressure in the rigid pipe 402, which represents respective sucking pressures generated in the suction ports 303A and 303B.

The substrate transfer apparatus of FIG. 1 is used to load semiconductor wafers in a wafer container and to unload them from the wafer container.

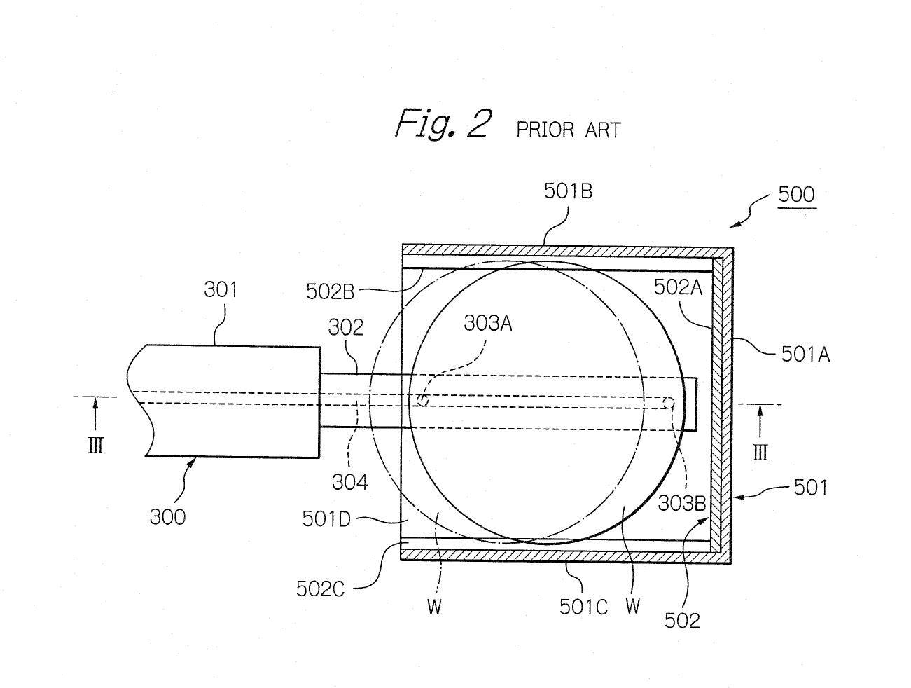

In particular, referring to FIG. 2 which is a cross-sectional view of the wafer container, the wafer container is generally indicated by reference numeral 500.

The wafer container 500 includes a box-like casing 501 having a rear wall portion 501A, side wall portions 501B and 501C integrally extending lateral sides of the rear wall portion 501A, a bottom wall portion 501D integrally extending a bottom side of the rear wall portion 501A, and a top wall portion (not shown) integrally extending a top side of the rear wall portion 501A.

The wafer container 500 also includes a plurality of U-shaped shelves 502 provided in the box-like casing 501 so as to be vertically arranged at regular intervals. Note, in FIG. 2, only one of the U-shaped shelves 502 is visible.

The U-shaped shelf 502 has an elongated base member 502A securely attached to an inner wall face of the rear wall portion 501A, and two pairs of rib-like side members 502B and 502C integrally extending from the respective ends of the elongated base member 502A and securely attached to inner wall faces of the respective side wall portions 501B and 501C.

Note, in FIG. 2, only one of the pair of rib-like side members 502B, which are attached to the inner wall face of the side wall portion 501B, is illustrated, and only one of the pair of rib-like side members 502C, which are attached to the inner wall face of the side wall portion 501C, is illustrated.

As shown in FIG. 2, a semiconductor wafer, indicated by reference W, is held by the U-shaped shelf 502. Namely, in the U-shaped shelf 502, the two pairs of rib-like side members 502B and 502C define opposite side grooves, and two diametrical side edge areas of the semiconductor wafer W are received in the respective opposite side grooves, whereby the semiconductor wafer W is held by the U-shaped shelf 502.

Note, in FIG. 2, the semiconductor wafer W drawn by a solid line is placed at a proper position in the U-shaped shelf 502, whereas the semiconductor wafer W drawn by a one-dot chain line is placed at an improper position in the U-shaped shelf 502.

As shown in FIG. 2, for example, when the semiconductor wafer W placed at the proper position is unloaded from the wafer container 500 by the substrate transfer apparatus of FIG. 1, the drive unit 200 is moved by the X-Y table unit 100 such that the pneumatic sucker arm 300 is positioned in place beneath the semiconductor wafer W. Then, the drive unit 200 is driven so that the movable column 202 is upwardly moved until the upper face of the sucker portion 301 of the pneumatic sucker arm 300 is contacted with the semiconductor wafer W.

Next, the vacuum pump 401 is operated so that the semiconductor wafer W is pneumatically sucked by the suction ports 303A and 303B, whereby the semiconductor wafer W is pneumatically held by the sucker portion of the pneumatic sucker arm 300. Then, by driving the drive unit 200, the movable column 202 is moved somewhat upwardly so that the diametrical side edge areas of the semiconductor wafer W are floated in the opposite grooves defined by the two pairs of rib-like side members 502B and 502C of the U-shaped shelf 502. Subsequently, the drive unit 200 is moved by the X-Y table unit 100 such that the pneumatic sucker arm 300 carrying the sucked semiconductor wafer W is extracted from the wafer container 500, resulting in completion of the unloading of the semiconductor wafer W from the wafer container 500.

In the substrate transfer apparatus of FIG. 1, the pressure sensor 404 for detecting the internal pressure in the rigid pipe 402 is used to determine whether the semiconductor wafer W is properly held by the sucker portion 301 of the pneumatic sucker arm 300.

In particular, when the semiconductor wafer W is pneumatically sucked by both the suction ports 303A and 303B, i.e., when the semiconductor wafer W is properly held by the sucker portion 301 of the pneumatic sucker arm 300, the internal pressure in the rigid pipe 402 is lowered to a predetermined low pressure. Thus, when the predetermined low pressure is detected by the pressure sensor 404, it is possible to determine that the proper holding of the semiconductor wafer W by the sucker portion 301 has been carried out.

On the other hand, when the semiconductor wafer W is placed at the improper position as drawn by the one-dot chain line in FIG. 2, the semiconductor wafer W is pneumatically sucked by only the suction port 303A so that the internal pressure in the rigid pipe 402 cannot be lowered to the predetermined low pressure. Namely, when the pressure sensor 404 detects a higher pressure than the predetermined low pressure, it is possible to determine that the semiconductor wafer W is improperly held by the sucker portion 301. In this case, the unloading of the semiconductor wafer W from the wafer container 500 is interrupted, and an unloading of the semiconductor wafer W from the wafer container 500 is retried by adjusting a position of the pneumatic sucker arm 300 so that the semiconductor wafer W is properly held by the sucker portion 301.

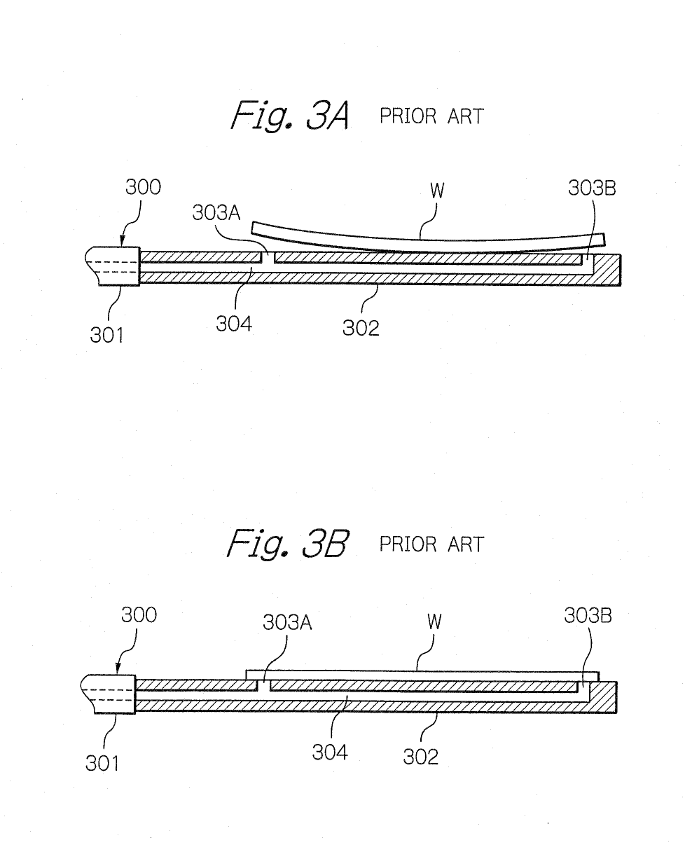

Incidentally, the diameter of the semiconductor wafer W becomes larger to manufacture a large amount of semiconductor device chips or integrated circuit chips at low cost. Also, with the recent advance in scaling and integration of semiconductor devices, the thickness of the semiconductor wafer W becomes thinner. During the manufacture of the semiconductor devices, the semiconductor wafer W is subjected to thermal stresses or the like, resulting in warpage of the semiconductor wafer W. The warpage of the semiconductor wafer W is amplified by increasing the wafer diameter and decreasing the wafer thickness, so that it is very difficult or impossible to properly handle the semiconductor wafer W by the substrate transfer apparatus of FIG. 1, as will be stated below with reference to FIGS. 3A and 3B.

FIGS. 3A and 3B are cross-sectional views taken along the III-III line of FIG. 2. Note, in FIGS. 3A and 3B, the wafer container 500 (see: FIG. 2) is omitted to avoid complexity of illustration.

As shown in FIG. 3A, in the case when the semiconductor wafer W is warped and the respective front and back surfaces of the semiconductor wafer W are defined as concave and convex surfaces, the semiconductor wafer W cannot be pneumatically sucked by both the suction ports 303A and 303B due to the warpage of the semiconductor wafer W, and it is impossible to hold and transfer the warped semiconductor wafer W.

As shown in FIG. 3B, the suction force caused by the vacuum pump 401 (see: FIG. 1) may be increased so that the warpage is eliminated from the semiconductor wafer W, whereby the semiconductor wafer W can be pneumatically sucked by both the suction ports 303A and 303B. Nevertheless, this procedure cannot be adopted because the semiconductor wafer W may be subjected to mechanical damage due to the elimination of the warpage from the semiconductor wafer W. Namely, when the warpage is eliminated from the semiconductor wafer W, tensile stresses are produced in the front surface side of the semiconductor wafer W so that cracks may penetrate in various thin film-like layers formed in the semiconductor wafer W.

### First Embodiment

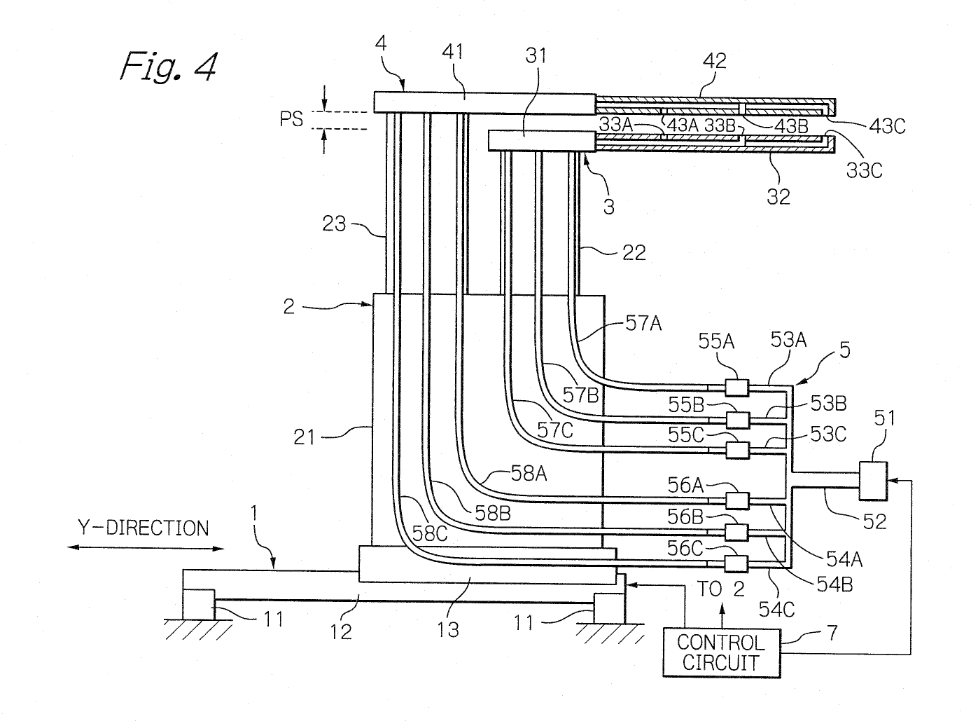

First, referring to FIG. 4 which is a schematic view of a first embodiment of the substrate transfer apparatus according to the present invention, the substrate transfer apparatus includes an X-Y table unit 1 which has a pair of guide rails 11 laid on a floor so as to be extended in an X-direction in parallel with the guide rails 11, a pair of guide rails 12 slidably provided on the pair of guide rails 11 and extended in a Y-direction perpendicular to the X-direction, and an X-Y table 13 slidably provided on the pair of guide rails 12. Note, in FIG. 4, only one of the guide rails 12 is visible.

Although not illustrated in FIG. 4, the X-Y table unit 1 is provided with a drive mechanism for moving the guide rails 12 along the guide rails 11, and a drive mechanism for moving the X-Y table 13 along the guide rails 12. Each of the drive mechanisms may be formed as a ball/screw mechanism for converting a rotational movement into a translational movement.

With the above-mentioned arrangement of the X-Y table unit 1, it is possible to suitably move the X-Y table 13 in the X-direction and/or the Y-direction.

The substrate transfer apparatus also includes a drive unit 2 provided on the X-Y table 13, and the drive unit 2 has a housing 21 securely mounted on the X-Y table 13, and a pair of movable columns 22 and 23 provided in the housing 21 so as to be vertically moved.

Although not illustrated in FIG. 4, the drive unit 2 contains two drive mechanisms which are provided in the housing 21 to vertically move the respective columns 22 and 23. For example, each of the drive mechanisms may be formed as a rack/pinion mechanism for converting a rotational movement into a translational movement.

The substrate transfer apparatus further includes a pair of lower and upper pneumatic sucker arms 3 and 4 which are provided on respective top ends of the movable columns 22 and 23 to suck and hold a substrate such as a semiconductor wafer. The lower pneumatic sucker arm 3 includes a base portion 31 securely attached to the top of the movable column 22, and a sucker portion 32 integrally extending therefrom. Similarly, the upper pneumatic sucker arm 4 includes a base portion 41 securely attached to the top of the movable column 23, and a sucker portion 42 extending therefrom. In short, the lower and upper pneumatic sucker arms 3 and 4 are supported by the respective movable columns 22 and 23 in a cantilever manner.

Note, usually, both the lower and upper pneumatic sucker arms 3 and 4 are vertically and synchronously moved so that a predetermined space PS is defined and maintained therebetween.

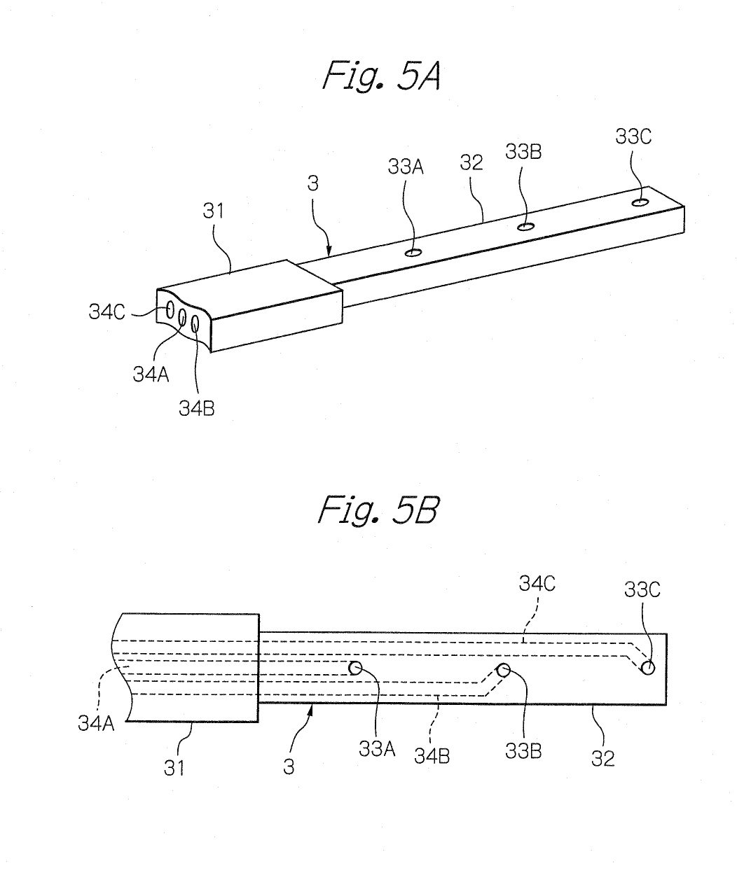

Referring to FIGS. 5A and 5B which are respectively partially-perspective and partial plan views of the lower pneumatic sucker arm 3, the sucker portion 32 has three suction ports 33A, 33B and 33C formed in an upper face thereof, and three air passages 34A, 34B and 34C are formed in both the base portion 31 and the sucker portion 32 so as to be in communication with the respective suction ports 33A, 33B and 33C. Preferably, the suction ports 33A, 33B and 33C are aligned with each other at regular intervals along a central longitudinal axis of the sucker portion 32.

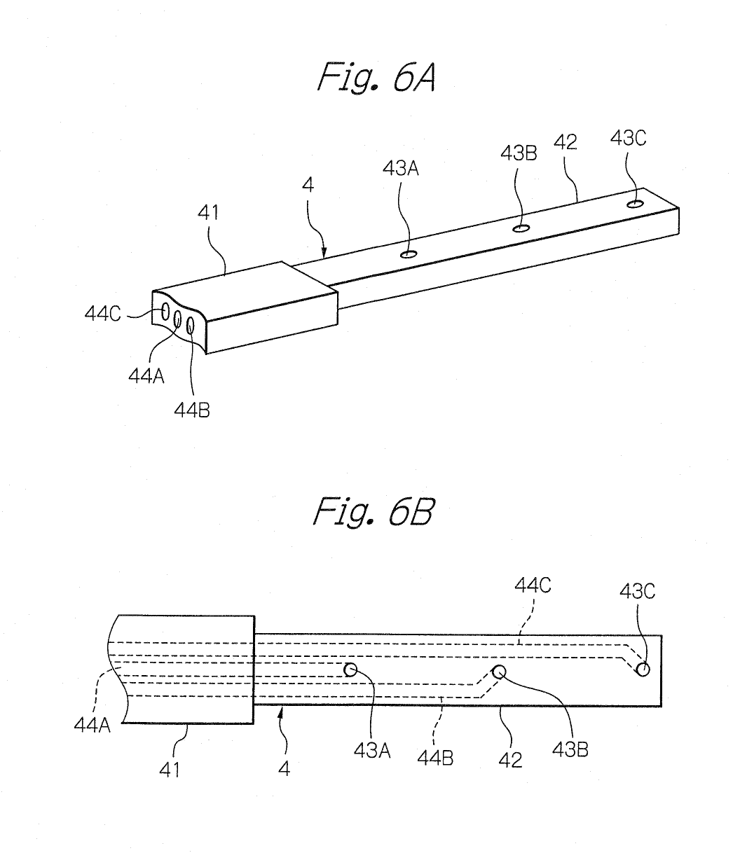

Referring to FIGS. 6A and 6B which are respectively partially-perspective and partial bottom views of the upper pneumatic sucker arm 4, the sucker portion 42 has three suction ports 43A, 43B and 43C formed in a bottom face thereof, and three air passages 44A, 44B and 44C are formed in both the base portion 41 and the sucker portion 42 so as to be in communication with the respective suction ports 43A, 43B and 43C. Preferably, the suction ports 43A, 43B and 43C are aligned with each other at regular intervals along a central longitudinal axis of the sucker portion 42.

Returning to FIG. 4, the substrate transfer apparatus further includes a vacuum suction unit 5 associated with both the lower and upper pneumatic sucker arms 3 and 4. The vacuum suction unit 5 has a vacuum pump 51 and a rigid piping fixture 52 which are suitably installed in place. The rigid piping fixture 52 has three rigid pipes 53A, 53B and 53C and three rigid pipes 54A, 54B and 54C which are connected to the vacuum pump 51.

The respective rigid pipes 53A, 53B and 53C are provided with pressure sensors 55A, 55B and 55C to thereby detect internal pressures in the respective rigid pipes 53A, 53B and 53C, which represent sucking pressures generated in the respective suction ports 33A, 33B and 33C.

Similarly, the respective rigid pipes 54A, 54B and 54C are provided with pressure sensors 56A, 56B and 56C to thereby detect internal pressures in the respective rigid pipes 54A, 54B and 54C, which represent sucking pressures generated in the respective suction ports 43A, 43B and 43C.

The vacuum suction unit 5 also has three flexible exhaust conduits 57A, 57B and 57C connected to the respective rigid pipes 53A, 53B and 53C, and three flexible exhaust conduits 58A, 58B and 58C connected to the respective rigid pipes 54A, 54B and 54C. The flexible exhaust conduits 57A, 57B and 57C are connected to the base portion 31 of the lower pneumatic sucker arm 3 so as to be in communication with the respective air passages 34A, 34B and 34C (see: FIGS. 5A and 5B). Similarly, the flexible exhaust conduits 58A, 58B and 58F are connected to the base portion 41 of the upper pneumatic sucker arm 4 to as to be in communication with the respective air passages 44A, 44B and 44C (see: FIGS. 6A and 6B).

As shown in FIG. 4, the substrate transfer apparatus is provided with a control circuit 7 which receives analog signals from the pressure sensors 55A, 55B, 55C, 56A, 56B and 56C, and which controls the X-Y table unit 1, the drive unit 2 and the vacuum pump 51, as will be stated in detail hereinafter.

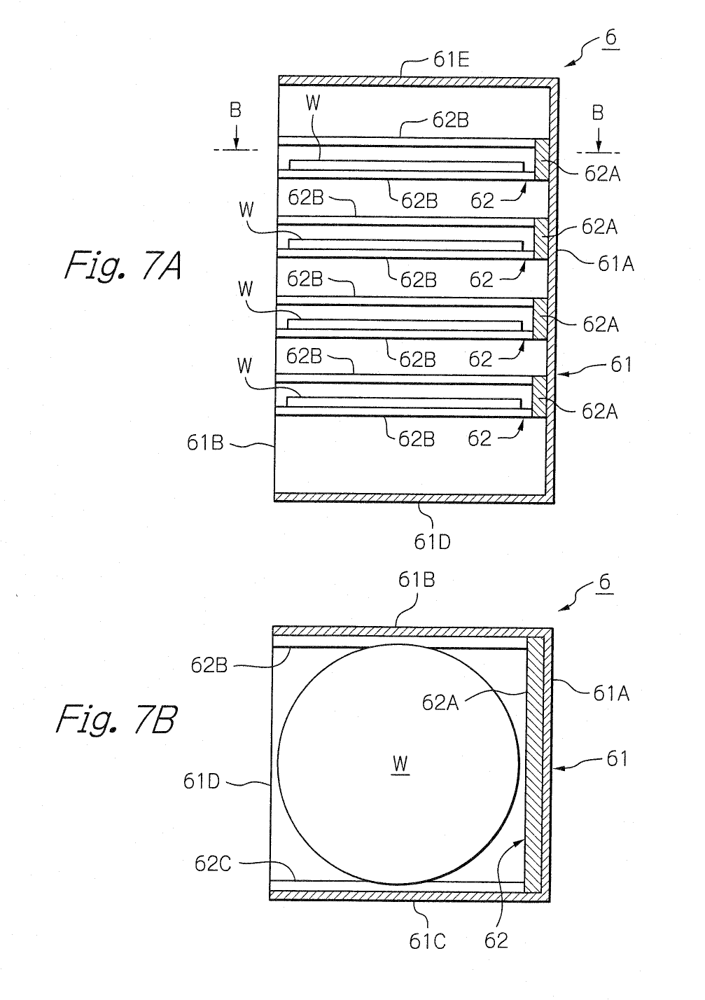

With reference to FIGS. 7A and 7B, a wafer container, in and from which semiconductor wafers are loaded and unloaded by the substrate transfer apparatus of FIG. 4, is generally indicated by reference numeral 6. Note, FIG. 7A is a longitudinally-sectional view of the wafer container 8, and FIG. 7B is a cross-sectional view taken along the B-B line of FIG. 7A.

As shown in FIGS. 7A and 7B, the wafer container 6 includes a box-like casing 61 having a rear wall portion 61A, side wall portions 61B and 61C (see: FIG. 7B) integrally extending lateral sides of the rear wall portion 61A, a bottom wall portion 61D integrally extending a bottom side of the rear wall portion 61A, and a top wall portion 61E (see: FIG. 7A) integrally extending a top side of the rear wall portion 61A.

The wafer container 6 also includes four U-shaped shelves 62 provided in the box-like casing 61 so as to be vertically arranged at regular intervals. Each of the U-shaped shelves 62 has an elongated base member 62A securely attached to an inner wall face of the rear wall portion 61A, and two pairs of rib-like side members 62B (see: FIGS. 7A and 7B) and 62C (see: FIG. 7B) integrally extending from the respective ends of the elongated base member 62A and securely attached to inner wall faces of the respective side wall portions 61B and 61C. Note, in FIG. 7B, only one of the pair of rib-like side members 62C, which are attached to the inner wall face of the side wall portion 61C, is illustrated.

As shown in FIGS. 7A and 7B, semiconductor wafers, indicated by reference W, are held by the respective U-shaped shelves 62. Namely, in each of the U-shaped shelves 62, the two pairs of rib-like side members 62B and 62C define opposite side grooves, and diametrical side edge areas of a semiconductor wafer W are received in the respective opposite side grooves, whereby the semiconductor wafer W is held by the corresponding U-shaped shelf 62.

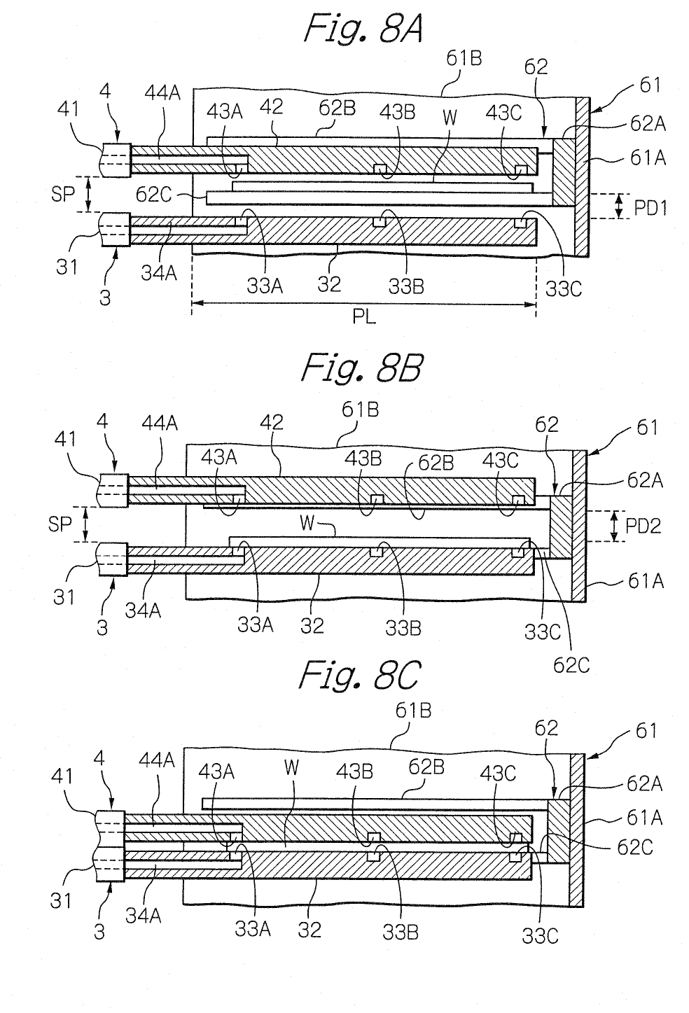

With reference to FIGS. 8A, 8B and 8C corresponding to partially-enlarged views of FIG. 7A, how to unload one of the semiconductor wafers W from the wafer container 6 by the substrate transfer apparatus of FIG. 4 is explained by way of example below.

Note, when one of the semiconductor wafers W is unloaded from the wafer container 6, the drive unit 2 (see: FIG. 4) is positioned at the front of the wafer container 6 by driving the X-Y table unit 1, and both the lower and upper pneumatic sucker arms 3 and 4 are vertically and synchronously moved to be positioned in place with respect to one of the semiconductor wafers W so that the semiconductor wafer W concerned is brought to a mid point between the lower and upper pneumatic sucker arms 3 and 4 which are apart from each other by the predetermined space PS.

First, as shown in FIG. 8A, after the positioning of both the lower and upper pneumatic sucker arms 3 and 4 with respect to the semiconductor wafer W concerned is carried out, the drive unit 2 is moved in the Y-direction (see: FIG. 4) so that both the sucker portions 32 and 42 of the lower and upper pneumatic sucker arms 3 and 4 are entered into the interior of the wafer container 6 by a predetermined length PL, with the semiconductor wafer W being intervened between the lower and upper pneumatic sucker arms 3 and 4. At this time, a position of both the lower and upper pneumatic sucker arms 3 and 4 is defined as an unloading-ready position. Note, at the unloading-ready position, the sucker portion 32 of the lower pneumatic sucker arm 3 is spaced apart from the back surface of the semiconductor wafer W by a predetermined distance PD1.

After both the lower and upper pneumatic sucker arms 3 and 4 are positioned at the unloading-ready position, the vacuum pump 51 (see: FIG. 4) is operated, and then the lower pneumatic sucker arm 3 is upwardly moved toward the back surface of the semiconductor wafer W. During the upward movement of the lower pneumatic sucker arm 3, respective variations of the internal pressures in the rigid pipes 53A, 53B and 53C (see: FIG. 4) are monitored by the pressure sensors 55A, 55B and 55C (see: FIG. 4).

As shown in FIG. 8B, when the upper face of the sucker portion 32 of the lower pneumatic sucker arm 3 is contacted with the back surface of the semiconductor wafer W, i.e., when the semiconductor wafer W is pneumatically sucked and held by one of the suction ports 33A, 33B and 33C, the upward movement of the lower pneumatic sucker arm 3 is stopped. In particular, when the semiconductor wafer W is pneumatically sucked and held by one of the suction ports 33A, 33B and 33C, the internal pressure in the corresponding one of the rigid pipes 53A, 53B and 53C is lowered to a predetermined low pressure, and the predetermined low pressure can be detected by the corresponding one of the pressure sensors 55A, 55B and 55C. Namely, when the predetermined low pressure is detected by one of the pressure sensors 55A, 55B and 55C, the upward movement of the lower pneumatic sucker arm 3 is stopped. At this time, the sucker portion 42 of the upper pneumatic sucker arm 4 is spaced apart from the front surface of the semiconductor wafer W by a predetermined distance PD2.

In the example of FIGS. 8A, 8B and 8C, since the semiconductor wafer W is flat, the three suction ports 33A, 33B and 33C may be simultaneously brought into contact with the back surface of the semiconductor wafer W, and thus the semiconductor wafer W may be pneumatically sucked and held by all the suction ports 33A, 33B and 33C. Note that the endmost suction ports 33A and 33C are spaced apart from each other so as to be in contact with two diametrical side edge areas on the back surface of the semiconductor wafer W.

After the upward movement of the lower pneumatic sucker arm 3 is stopped, i.e., after the semiconductor wafer W is pneumatically sucked and held by all the suction ports 33A, 33B and 33C, the upper pneumatic sucker arm 4 is downwardly moved toward the front surface of the semiconductor wafer W. During the downward movement of the upper pneumatic sucker arm 4, respective variations of the internal pressures in the rigid pipes 54A, 54B and 54F (see: FIG. 4) are monitored by the pressure sensors 56A, 56B and 56C (see: FIG. 4).

As shown in FIG. 8C, when the lower face of the sucker portion 42 of the upper pneumatic sucker arm 4 is in contact with the front surface of the semiconductor wafer W, i.e., when the semiconductor wafer W is pneumatically sucked and held by one of the suction ports 43A, 43B and 43C, the downward movement of the upper pneumatic sucker arm 4 is stopped. In particular, when the semiconductor wafer W is pneumatically sucked and held by one of the suction ports 43A, 43B and 43C, the internal pressure in the corresponding one of the rigid pipes 54A, 54B and 54C is lowered to a predetermined low pressure, and the predetermined low pressure can be detected by the corresponding one of the pressure sensors 56A, 56B and 56C. Namely, when the predetermined low pressure is detected by one of the pressure sensors 56A, 56B and 56C, the downward movement of the upper pneumatic sucker arm 4 is stopped.

In the example of FIGS. 8A, 8B and 8C, since the semiconductor wafer W is flat, the three suction ports 43A, 43B and 43C may be simultaneously brought into contact with the front surface of the semiconductor wafer W, and thus the semiconductor wafer W may be pneumatically sucked and held by all the suction ports 43A, 43B and 43C. Note that the endmost suction ports 43A and 43C are spaced apart from each other so as to be in contact with two diametrical side edge areas on the front surface of the semiconductor wafer W, in which no semiconductor devices are formed.

After the semiconductor wafer W is pneumatically sucked and held by both the sucker portions 32 and 42 of the lower and upper pneumatic sucker arms 3 and 4, both the lower and upper pneumatic sucker arms 3 and 4 are moved somewhat upwardly so that the diametrical side edge areas of the semiconductor wafer W are floated in the opposite side grooves defined by the two pairs of rib-like side members 62B and 62C of the corresponding U-shaped shelf 62. Subsequently, the drive unit 2 is moved in the Y-direction by the X-Y table unit 1 such that both the lower and upper pneumatic sucker arms 3 and 4 carrying the sucked semiconductor wafer W are extracted from the wafer container 6, resulting in completion of the unloading of the semiconductor wafer W from the wafer container 6.

Note that it is possible to load a semiconductor wafer W in the wafer container 6 by reversely carrying out the aforesaid procedures of the unloading of the semiconductor wafer W.

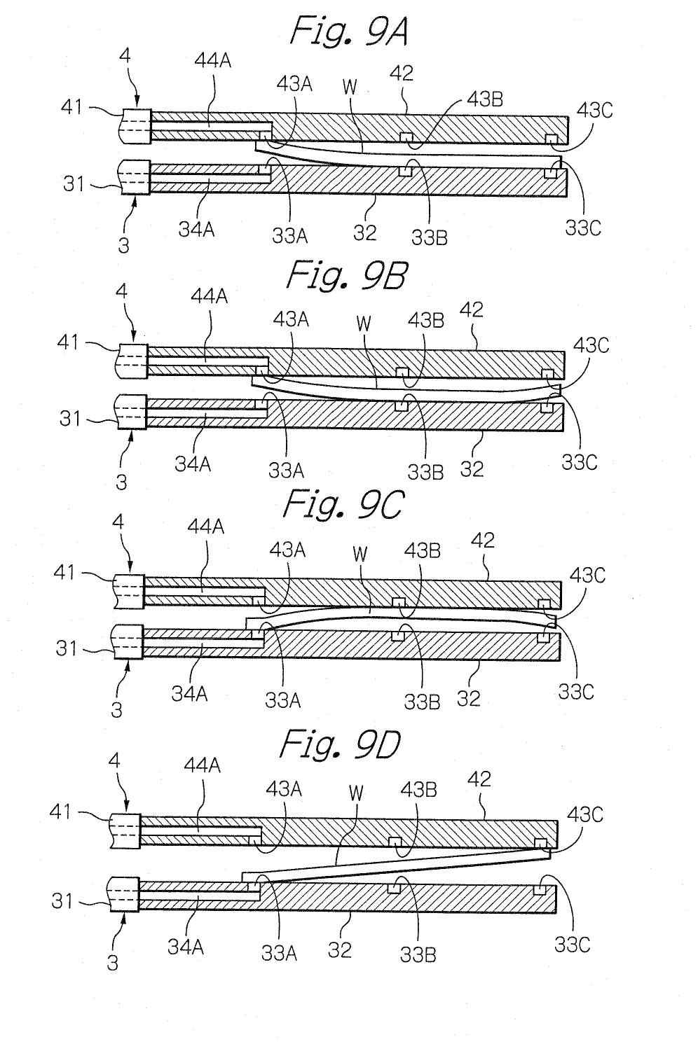

In FIGS. 9A, 9B, 9C and 9D which correspond to FIG. 8C, representative examples of warpage of the semiconductor wafer W are illustrated. Note, in FIGS. 9A to 9D, the semiconductor container 6 (FIG. 8C) is omitted to avoid complexity of illustration.

First, referring to FIG. 9A, the semiconductor wafer W is warped so that the back surface of the semiconductor wafer W is pneumatically sucked by only the two suction ports 33B and 33C of the sucker portion 32 of the lower pneumatic sucker arm 3, and so that the front surface of the semiconductor wafer W is pneumatically sucked by only the suction port 43A of the sucker portion 42 of the upper pneumatic sucker arm 4.

In the example of FIG. 9A, the semiconductor wafer W may be oriented in the U-shaped shelf 62 (see: FIG. 8C) so that the back surface of the semiconductor wafer W is pneumatically sucked by only the two suction ports 33A and 33B of the sucker portion 32 of the lower pneumatic sucker arm 3, and so that the front surface of the semiconductor wafer W is pneumatically sucked by only the suction port 43C of the sucker portion 42 of the upper pneumatic sucker arm 4.

Next, referring to FIG. 9B, the semiconductor wafer W is warped so that the back surface of the semiconductor wafer W is pneumatically sucked by only the suction port 33B of the sucker portion 32 of the lower pneumatic sucker arm 3, and so that the front surface of the semiconductor wafer W is pneumatically sucked by only the suction port 43A of the sucker portion 42 of the upper pneumatic sucker arm 4.

In the example of FIG. 9B, the semiconductor wafer W may be oriented in the U-shaped shelf 62 (see: FIG. 8C) so that the back surface of the semiconductor wafer W is pneumatically sucked by only the suction port 33B, and so that the front surface of the semiconductor wafer W is pneumatically sucked by only the suction port 43C.

Next, referring to FIG. 9C, the semiconductor wafer W is warped so that the back surface of the semiconductor wafer W is pneumatically sucked by only the suction port 33A of the sucker portion 32 of the lower pneumatic sucker arm 3, and so that the front surface of the semiconductor wafer W is pneumatically sucked by only the suction port 43B of the sucker portion 42 of the upper pneumatic sucker arm 4.

In the example of FIG. 9C, the semiconductor wafer W may be oriented in the U-shaped shelf 62 (see: FIG. 8C) so that the back surface of the semiconductor wafer W is pneumatically sucked by only the suction port 33C, and so that the front surface of the semiconductor wafer W is pneumatically sucked by only the suction port 43B.

Next, referring to FIG. 9D, the semiconductor wafer W is warped so that the back surface of the semiconductor wafer W is pneumatically sucked by only the suction port 33A of the sucker portion 32 of the lower pneumatic sucker arm 3, and so that the front surface of the semiconductor wafer W is pneumatically sucked by only the suction port 43C of the sucker portion 42 of the upper pneumatic sucker arm 4.

In the example of FIG. 9D, the semiconductor wafer W may be oriented in the U-shaped shelf 62 (see: FIG. 8C) so that the back surface of the semiconductor wafer W is pneumatically sucked by only the suction port 33C, and so that the front surface of the semiconductor wafer W is pneumatically sucked by only the suction port 43A.

In any case, in the substrate transfer apparatus of FIG. 4, each of the warped semiconductor wafers W can be stably and securely held by using the lower and upper pneumatic sucker arms 3 and 4.

Note, according to the present invention, the suction force caused by the vacuum pump 51 (see: FIG. 4) cannot be increased so as to eliminate the warpage from the semiconductor wafer W.

As shown in FIG. 8B or FIG. 9A, when the semiconductor wafer W is pneumatically sucked by at least two suction ports 33A and 33B, 33A and 33C or 33B and 33C of the sucker portion 32 of the lower pneumatic sucker arm 3, the semiconductor wafer W may be unloaded from the wafer container 6 without utilizing the upper pneumatic sucker arm 4.

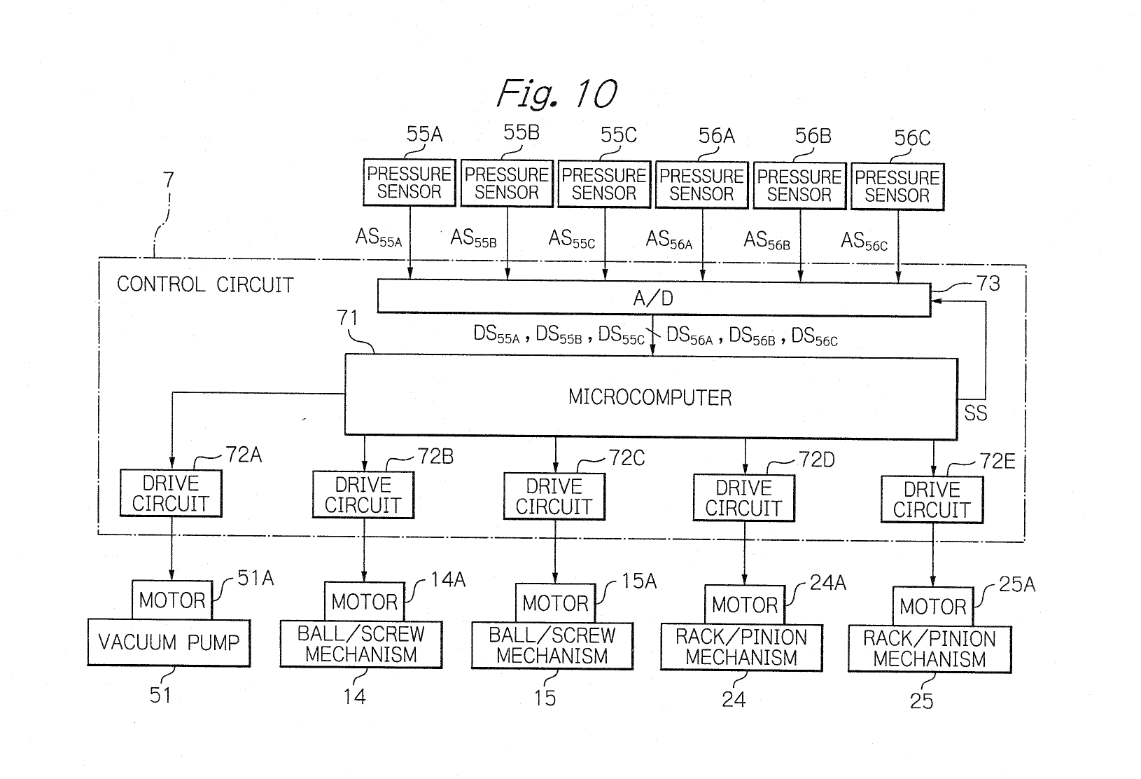

FIG. 10 shows a block circuit diagram of the control circuit 7 of FIG. 4.

The control circuit 7 has a microcomputer 71, drive circuits 72A, 72B, 72C, 72D and 72E, and an analog-to-digital (A/D) converter 73 containing a multiplexer.

The microcomputer 71 includes a central processing unit (CPU), a read-only memory (ROM) for storing various programs and constants, a random-access memory (RAM) for storing temporary data, an input/output (I/O) interface circuit and so on. The drive circuits 72A to 72E and the A/D converter 73 are connected to the CPU through the intermediary of the I/O interface circuit. Note, although not illustrated in FIG. 10, a display unit, a keyboard and so on are connected to the microcomputer 71.

As stated above, when the semiconductor wafer W is pneumatically sucked by one of the suction ports 33A, 33B, 33C, 43A, 43B and 43C (FIG. 8C), the internal pressure in the corresponding one of the rigid pipes 52A, 52B, 52C, 52D, 52E and 52F) is lowered to the predetermined low pressure. The ROM of the microcomputer 71 stores low pressure data LP corresponding to the aforesaid predetermined low pressure.

In FIG. 10, the vacuum pump 51 (see: FIG. 4) is shown as a block, and has a suitable electric motor 51A which is driven by the drive circuit 72A under control of the microcomputer 71.

Also, in FIG. 10, the ball/screw mechanism for moving the guide rails 12 (see: FIG. 4) in the X-direction is indicated by reference numeral 14, and the ball/screw mechanism for moving the X-Y table 13 (see: FIG. 4) in the Y-direction is indicated by reference numeral 15. The respective ball/screw mechanisms 14 and 15 have suitable electric motors 14A and 15A such as stepping motors, servo motors or the like, which are driven by the drive circuit 72B and 72C under control of the microcomputer 71.

Further, in FIG. 10, the respective rack/pinion mechanisms for vertically moving the movable columns 22 and 23 (see: FIG. 4) are indicated by reference numerals 24 and 25, and have suitable electric motors 24A and 25A such as stepping motors, servo motors or the like, which are driven by the drive circuit 72D and 72E under control of the microcomputer 71.

On the other hand, in FIG. 10, the pressure sensors 55A, 55B, 55C, 56A, 56B and 56C (see: FIG. 4) are shown as blocks, and are connected to the A/D converter 73. The respective internal pressures in the rigid pipes 53A, 53B, 53C, 54A, 54B and 54C (see: FIG. 4) are detected as analog signals AS_{55A}, AS_{55B}, AS_{55C}, AS_{56A}, AS_{55B} and AS_{56C} by the pressure sensors 55A, 55B, 55C, 56A, 56B and 56C. The respective analog signals AS_{55A}, AS_{55B}, AS_{55C}, AS_{56A}, AS_{56B} and AS_{56C} are converted into digital signals DS_{55A}, DS_{55B}, DS_{55C}, DS_{56A}, DS_{56B} and DS_{56C} by the A/D converter 73, and each of the digital signals is transmitted from the A/D converter 73 to the microcomputer 71 in accordance with a selection signal SS output from the microcomputer 71 to the A/D converter 73.

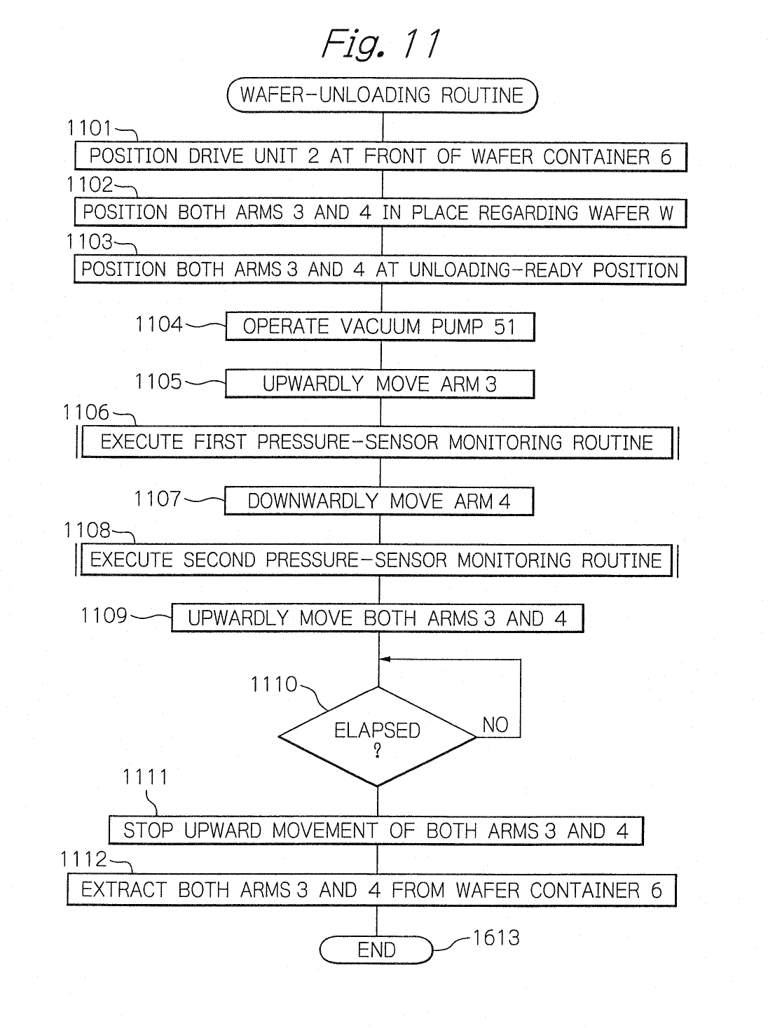

FIG. 11 shows a flowchart of a wafer-unloading routine executed in the microcomputer 71 of FIG. 10.

Note, when the wafer-unloading routine is executed, the semiconductor wafers W are previously held by the U-shaped shelves 62 of the wafer container 6 (see: FIG. 7A).

First, at step 1101, the drive unit 2 (see: FIG. 4) is positioned at the front of the wafer container 6 (see: Fig. FIGS. 7A and 7B) by driving the electric motors 14A and 15A of the ball/screw mechanisms 14 and 15 (see: FIG. 10), with a space between the lower and upper pneumatic sucker arms 3 and 4 being set into the predetermined space PS (see: FIG. 8A).

Next, at step 1102, both the lower and upper pneumatic sucker arms 3 and 4 are vertically and synchronously moved by driving the electric motors 24A and 25A of the rack/pinion mechanisms 24 and 25 (see: FIG. 10) to be positioned in place with respect to one of the semiconductor wafers W so that the semiconductor wafer W concerned is brought to the mid point between the lower and upper pneumatic sucker arms 3 and 4.

Next, at step 1103, the drive unit 2 is moved in the Y-direction (see: FIG. 4) by driving the electric motor 15A of the ball/screw mechanism 15 (see: FIG. 10) so that both the sucker portions 32 and 42 of the lower and upper pneumatic sucker arms 3 and 4 are entered into the interior of the wafer container 6 by the predetermined length PL (see: FIG. 8A), with the semiconductor wafer W being intervened between the lower and upper pneumatic sucker arms 3 and 4. Thus, both the lower and upper pneumatic sucker arms 3 and 4 are positioned at the unloading-ready position (see: FIG. 8A), with the sucker portion 32 of the lower pneumatic sucker arm 3 being spaced apart from the back surface of the semiconductor wafer W by the predetermined distance PD1 (see: FIG. 8A).

Next, at step 1104, the vacuum pump 51 (see: FIGS. 4 and 10) is operated by driving the electric motor 51A thereof. Then, at step 1105, the lower pneumatic sucker arm 3 is upwardly moved by driving the electric motor 24A of the rack/pinion mechanism 24 (see: FIG. 10).

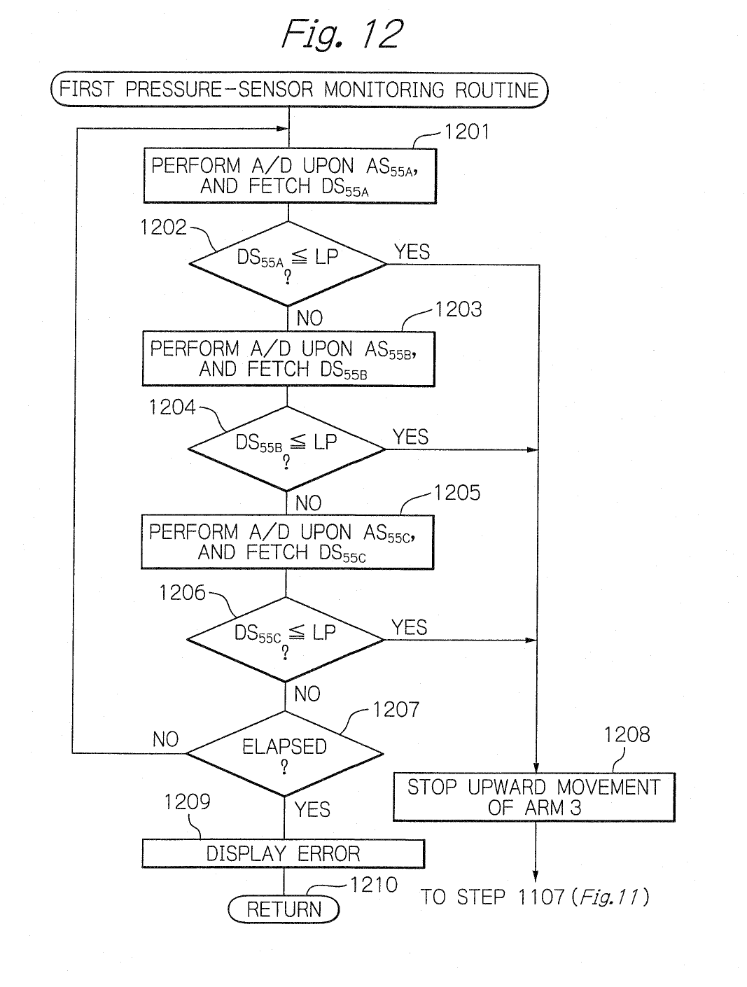

Next, at step 1106, a first pressure-sensor monitoring routine is executed to determine whether the semiconductor wafer W has been pneumatically sucked by any one of the suction ports 33A, 33B and 33C of the sucker portion 32 of the lower pneumatic sucker arm 3 (see: FIG. 8B). When it is confirmed that the semiconductor wafer W has been pneumatically sucked by any one of the suction ports 33A, 33B and 33C, the upward movement of the lower pneumatic sucker arm 3 is stopped. Note that the first pressure-sensor monitoring routine will be explained in detail with reference to FIG. 12.

Next, at step 1107, the upper pneumatic sucker arm 4 is downwardly moved by driving the electric motor 25A of the rack/pinion mechanism 25 (see: FIG. 10).

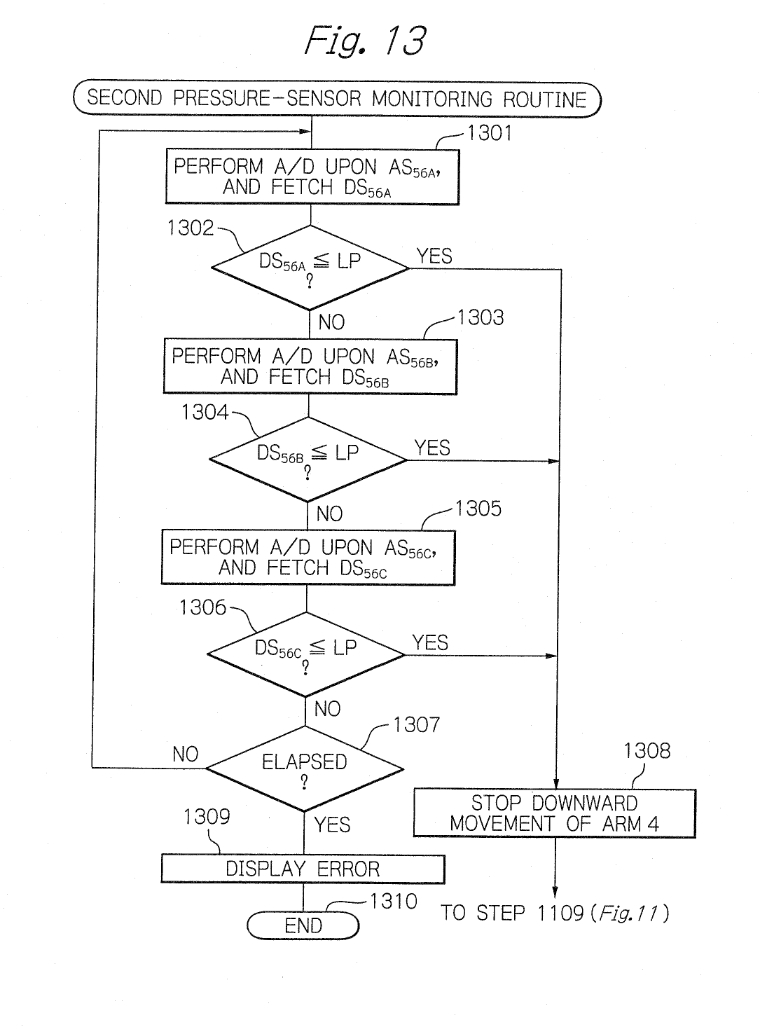

Next, at step 1108, a second pressure-sensor monitoring routine is executed to determine whether the semiconductor wafer W has been pneumatically sucked by any one of the suction ports 43A, 43B and 43C of the sucker portion 32 of the lower pneumatic sucker arm 3 (see: FIG. 8C). When it is confirmed that the semiconductor wafer W has been pneumatically sucked by any one of the suction ports 43A, 43B and 43C, the downward movement of the upper pneumatic sucker arm 4 is stopped. Note that the second pressure-sensor monitoring routine will be explained in detail with reference to FIG. 13.

Next, at step 1109, both the lower and upper pneumatic sucker arms 3 and 4 carrying the sucked semiconductor wafer W are upwardly moved by synchronously driving both the electric motors 24A and 25B of the rack/pinion mechanisms 24 and 25.

Next, at step 1110, it is monitored whether a given time has elapsed. Namely, it is monitored whether the diametrical side edge areas of the semiconductor wafer W have been floated in the opposite side grooves, defined by the two pairs of rib-like side members 62B and 62C of the corresponding U-shaped shelf 62 (FIG. 8C), due to the upward movement of both the lower and upper pneumatic sucker arms 3 and 4.

At step 1110, when it is confirmed that the given time has elapsed, the control proceeds to step 1111 in which the upward movement of both the lower and upper pneumatic sucker arms 3 and 4 is stopped.

Next, at step 1112, the drive unit 2 (see: FIG. 4) is moved in the Y-direction by driving the electric motor 14A of the ball/screw mechanism 14 so that both the lower and upper pneumatic sucker arms 3 and 4 carrying the sucked semiconductor wafer W are extracted from the wafer container 6, resulting in completion of the unloading of the semiconductor wafer W from the wafer container 6. Then, the routine of FIG. 11 is completed by step 1113.

FIG. 12 shows a detailed flowchart of a first example of the first pressure-sensor monitoring routine executed at step 1106 of FIG. 11.

First, at step 1201, the microcomputer 71 (see: FIG. 10) generates a selection signal SS for the pressure sensor 55A, so that the A/D converter 73 performs an A/D conversion upon an analog signal AS_{55A} of the pressure sensor 55A to thereby obtain a digital signal DS_{55A} representing an internal pressure in the rigid pipe 53A (see: FIG. 4). Then, the digital signal DS_{55A} is fetched by the microcomputer 71.

Next, at step 1202, it is determined whether the digital signal DS_{55A} is equal to or smaller than the low pressure data LP read from the ROM of the microcomputer 71. If DS_{55A}>LP, the control proceeds to step 1203.

Next, at step 1203, the microcomputer 71 (see: FIG. 10) generates a selection signal SS for the pressure sensor 55B, so that the A/D converter 73 performs an A/D conversion upon an analog signal AS_{55B} of the pressure sensor 55B to thereby obtain a digital signal DS_{55B} representing an internal pressure in the rigid pipe 53B (see: FIG. 4). Then, the digital signal DS_{55B} is fetched by the microcomputer 71.

Next, at step 1204, it is determined whether the digital signal DS_{55B} is equal to or smaller than the low pressure data LP. If DS_{55B}>LP, the control proceeds to step 1205.

Next, at step 1205, the microcomputer 71 (see: FIG. 10) generates a selection signal SS for the pressure sensor 55C, so that the A/D converter 73 performs an A/D conversion upon an analog signal AS_{55C} of the pressure sensor 55C to thereby obtain a digital signal DS_{55C} representing an internal pressure in the rigid pipe 53C (see: FIG. 4). Then, the digital signal DS_{55C} is fetched by the microcomputer 71.

Next, at step 1206, it is determined whether the digital signal DS_{55C} is equal to or smaller than the low pressure data LP. If DS_{55C}>LP, the control proceeds to step 1207.

Next, at step 1207, it is monitored whether a given time has elapsed. Namely, it is monitored whether the lower pneumatic sucker arm 3 has been upwardly moved from the unloading-ready position by the predetermined distance PD1 (see: FIG. 8A). When the lower pneumatic sucker arm 3 is still not upwardly moved by the predetermined distance PD1, the control returns to step 1201. That is, the control at steps 1201 to 1207 is repeated until it is determined that any one of the digital signals DS_{55A}, DS_{55B} and DS_{55C} is equal to or smaller than the low pressure data LP at step 1202, 1204 or 1206 or until it is determined that the lower pneumatic sucker arm 3 has been upwardly moved by the predetermined distance PD1.

At any one of steps 1202, 1204 and 1206, when it is determined that the digital signals DS_{55A}, DS_{55B} or DS_{55C} is equal to or smaller than the low pressure data LP, i.e., when it is determined that the semiconductor wafer W is pneumatically sucked by any one of the suction ports 33A, 33B and 33C (see: FIG. 8C), the control proceeds to step 1208, in which the upward movement of the lower pneumatic sucker arm 3 is stopped. Then, the control returns to step 1107 of the wafer-unloading routine of FIG. 11.

On the other hand, at step 1207, when the given time has elapsed without any one of the digital signals DS_{55A}, DS_{55B} and DS_{55C} being equal to or smaller than the low pressure data LP, i.e., without the semiconductor wafer W being pneumatically sucked by any one of the suction ports 33A, 33B and 33C (see: FIG. 8C), the control proceeds from step 1207 to step 1209, in which an error message is displayed on the display unit (not shown) connected to the microcomputer 71 (see: FIG. 10). Then, the routine of FIG. 12 is completed by step 1210.

FIG. 13 shows a detailed flowchart of the second pressure-sensor monitoring routine executed at step 1108 of FIG. 11.

First, at step 1301, the microcomputer 71 (see: FIG. 10) generates a selection signal SS for the pressure sensor 56A, so that the A/D converter 73 performs an A/D conversion upon an analog signal AS_{56A} of the pressure sensor 56A to thereby obtain a digital signal DS_{56A} representing an internal pressure in the rigid pipe 54A (see: FIG. 4). Then, the digital signal DS_{56A} is fetched by the microcomputer 71.

Next, at step 1302, it is determined whether the digital signal DS_{56A} is equal to or smaller than the low pressure data LP read from the ROM of the system controller 71. If DS_{56A}>LP, the control proceeds to step 1303.

Next, at step 1303, the microcomputer 71 (see: FIG. 10) generates a selection signal SS for the pressure sensor 56B, so that the A/D converter 73 performs an A/D conversion upon an analog signal AS_{56B} of the pressure sensor 56B to thereby obtain a digital signal DS_{56B} representing an internal pressure in the rigid pipe 54B (see: FIG. 4). Then, the digital signal DS_{56B} is fetched by the microcomputer 71.

Next, at step 1304, it is determined whether the digital signal DS_{56B} is equal to or smaller than the low pressure data LP. If DS_{56B}>LP, the control proceeds to step 1305.

Next, at step 1305, the microcomputer 71 (see: FIG. 10) generates a selection signal SS for the pressure sensor 56C, so that the A/D converter 73 performs an A/D conversion upon an analog signal AS_{56C} of the pressure sensor 56C to thereby obtain a digital signal DS_{56C} representing an internal pressure in the rigid pipe 54C (see: FIG. 4). Then, the digital signal DS_{56C} is fetched by the microcomputer 71.

Next, at step 1306, it is determined whether the digital signal DS_{56C} is equal to or smaller than the low pressure data LP. If DS_{56C}>LP, the control proceeds to step 1307.

Next, at step 1307, it is monitored whether a given time has elapsed. Namely, it is monitored whether the upper pneumatic sucker arm 3 has been downwardly moved by the predetermined distance PD2 (see: FIG. 8B). When the upper pneumatic sucker arm 4 is still not downwardly moved by the predetermined distance PD2, the control returns to step 1301, and the control at steps 1301 to 1307 is repeated until it is determined that any one of the digital signals DS_{56A}, DS_{56B} and DS_{56C} is equal to or smaller than the low pressure data LP at step 1302, 1304 or 1306 or until it is determined that the upper pneumatic sucker arm 4 has been downwardly moved by the predetermined distance PD2.

At any one of steps 1302, 1304 and 1306, when it is determined that the digital signals DS_{56A}, DS_{56B} or DS_{56C} is equal to or smaller than the low pressure data LP, i.e., when it is determined that the semiconductor wafer W is pneumatically sucked by any one of the suction ports 43A, 43B and 43C (see: FIG. 8C), the control proceeds to step 1308, in which the downward movement of the upper pneumatic sucker arm 4 is stopped. Then, the control returns to step 1109 of the wafer-unloading routine of FIG. 11.

On the other hand, at step 1307, when the given time has been elapsed without any one of the digital signals DS_{56A}, DS_{56B} and DS_{56C} being equal to or smaller than the low pressure data LP, i.e., without the semiconductor wafer W being not pneumatically sucked by any one of the suction ports 43A, 43B and 43C (see: FIG. 8C), the control proceeds from step 1307 to step 1309, in which an error message is displayed on the display unit (not shown) connected to the system controller 71 (see: FIG. 10). Then, the routine of FIG. 13 is completed by step 1310.

In the wafer-unloading routine of FIG. 11, the control at steps 1107 and 1108 may be executed before the control at steps 1105 and 1106 is executed. Namely, in this case, the sucking and holding of the semiconductor wafer W by the upper pneumatic sucker arm 4 is carried out prior to the sucking and holding of the semiconductor wafer W by the lower pneumatic sucker arm 3.

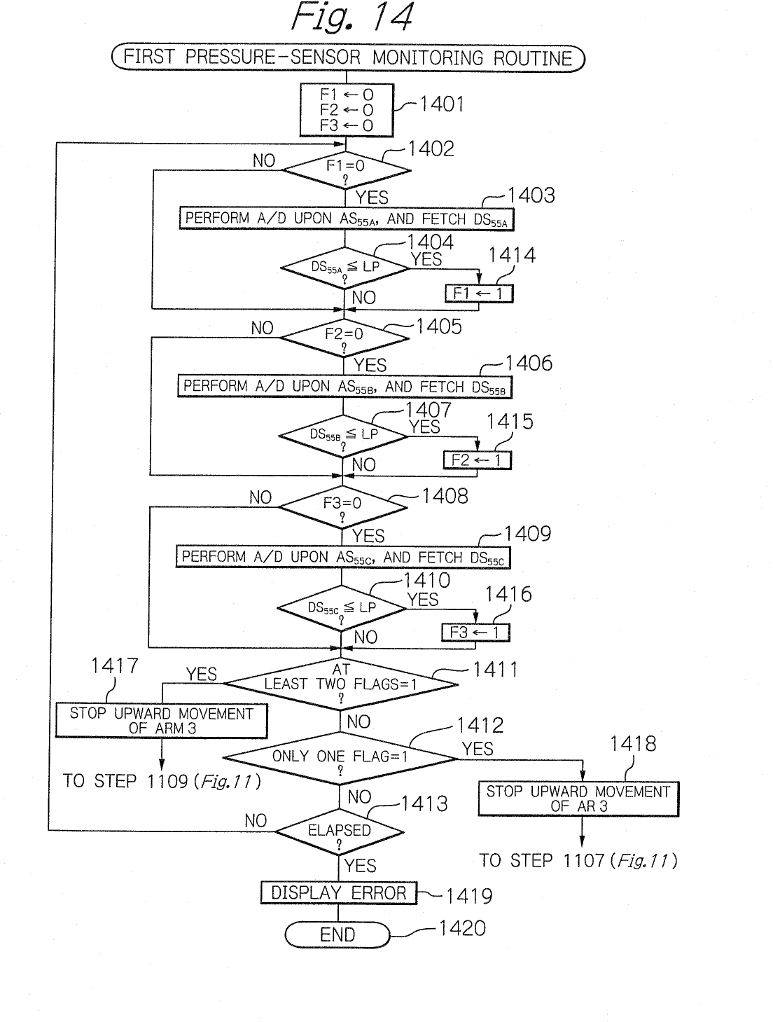

FIG. 14 shows a detailed flowchart of a second example of the first pressure-sensor monitoring routine executed at step 1106 of FIG. 11.

First, at step 1401, flags F1, F2 and F3 are initialized to be “0”. Note that the flags F1, F2 and F3 indicate whether the semiconductor wafer W is pneumatically sucked by the respective suction ports 33A, 33B and 33C.

Next, at step 1402, it is determined whether the flag F1 is “0” or “1”. At the initial stage, since F1=0, the control proceeds to step 1403, in which the microcomputer 71 (see: FIG. 10) generates a selection signal SS for the pressure sensor 55A, so that the A/D converter 73 performs an A/D conversion upon an analog signal AS_{55A} of the pressure sensor 55A to thereby obtain a digital signal DS_{55A} representing an internal pressure in the rigid pipe 53A (see: FIG. 4). Then, the digital signal DS_{55A} is fetched by the microcomputer 71.

Next, at step 1404, it is determined whether the digital signal DS_{55A} is equal to or smaller than the low pressure data LP read from the ROM of the system controller 71 (see: FIG. 10). If DS_{55A}>LP, the control proceeds to step 1405.

Next, at step 1405, it is determined whether the flag F2 is “0” or “1”. At the initial stage, since F2=0, the control proceeds to step 1406, in which the microcomputer 71 (see: FIG. 10) generates a selection signal SS for the pressure sensor 55B, so that the A/D converter 73 performs an A/D conversion upon an analog signal AS_{55B} of the pressure sensor 55B to thereby obtain a digital signal DS_{56B} representing an internal pressure in the rigid pipe 53B (see: FIG. 4). Then, the digital signal DS_{55B} is fetched by the microcomputer 71.

Next, at step 1407, it is determined whether the digital signal DS_{55B} is equal to or smaller than the low pressure data LP. If DS_{55B}>LP, the control proceeds to step 1408.

Next, at step 1408, it is determined whether the flag F3 is “0” or “1”. At the initial stage, since F3=0, the control proceeds to step 1409, in which the microcomputer 71 (see: FIG. 10) generates a selection signal SS for the pressure sensor 55C, so that the A/D converter 73 performs an A/D conversion upon an analog signal AS_{55C} of the pressure sensor 55C to thereby obtain a digital signal DS_{55C} representing an internal pressure in the rigid pipe 53C (see: FIG. 4). Then, the digital signal DS_{55C} is fetched by the microcomputer 71.

Next, at step 1410, it is determined whether the digital signal DS_{55C} is equal to or smaller than the low pressure data LP. If DS_{55C}>LP, the control proceeds to step 1411.

Next, at step 1411, it is determined whether at least two of the flags F1, F2 and F3 are “1”. When at least two of the flags F1, F2 and F3 are not “1”, the control proceeds to step 1412, in which it is determined whether only one of the F1, F2 and F3 is “1”. When all the F1, F2 and F3 are “0”, the control proceeds to step 1413.

Next, at step 1413, it is monitored whether a given time has elapsed. Namely, it is monitored whether the lower pneumatic sucker arm 3 has been upwardly moved from the unloading-ready position by the predetermined distance PD1 (see: FIG. 8A). When the lower pneumatic sucker arm 3 is still not upwardly moved by the predetermined distance PD1, the control returns to step 1402, and the control at steps 1402 to 1413 is repeated until it is determined that any one of the digital signals DS_{55A}, DS_{55B} and DS_{55C} is equal to or smaller than the low pressure data LP at step 1404, 1407 or 1410 or until it is determined that the lower pneumatic sucker arm 3 has been upwardly moved by the predetermined distance PD1.

In particular, at step 1404, when it is determined that the digital signal DS_{55A} is equal to or smaller than the low pressure data LP, i.e., when it is determined that the semiconductor wafer W is pneumatically sucked by the suction port 33A (see: FIG. 8C), the control proceeds from step 1404 to step 1414, in which the flag F1 is made to be “1”.

Also, at step 1407, when it is determined that the digital signal DS_{55B} is made to be equal to or smaller than the low pressure data LP, i.e., when it is determined that the semiconductor wafer W is pneumatically sucked by the suction port 33B (see: FIG. 8C), the control proceeds from step 1407 to step 1415, in which the flag F2 is made to be “1”.

Further, at step 1410, when it is determined that the digital signal DS_{55C} is made to be equal to or smaller than the low pressure data LP, i.e., when it is determined that the semiconductor wafer W is pneumatically sucked by the suction port 33C (see: FIG. 8C), the control proceeds from step 1410 to step 1416, in which the flag F3 is made to be “1”.

At step 1411, when at least two of the flags Ft, F2 and F3 are “1”, i.e., when F1=1 and F2=1, F1=1 and F3=1 or F2=1 and F3=1, the control proceeds from step 1414 to step 1417, in which the upward movement of the lower pneumatic sucker arm 3 is stopped. Then, the control returns to step 1109 of the wafer-unloading routine of FIG. 11.

Namely, when the semiconductor wafer W is pneumatically sucked by at least two of the suction ports 33A, 33B and 33C (F1=1 and F2=1, F1=1 and F3=1 or F2=1 and F3=1), and the unloading of the semiconductor wafer W is carried out without the semiconductor wafer W being held by the sucker portion 42 of the upper pneumatic sucker arm 4, because the pneumatic suction of the semiconductor wafer W by at least two of the suction ports 33A, 33B and 33C can ensure a stable holding of the semiconductor wafer W by the sucker portion 32 of the lower pneumatic sucker arm 3. In short, when the semiconductor wafer W is pneumatically sucked by at least two of the suction ports 33A, 33B and 33C, the upper pneumatic sucker arm 4 cannot be utilized.

Note that the holding of the semiconductor wafer W by the sucker portion 42 of the upper pneumatic sucker arm 4 should be avoided as much as possible, because some semiconductor devices on the front surface of the semiconductor wafer W may be mechanically damaged when the sucker portion 42 of the upper pneumatic sucker arm 4 is contacted with the front surface of the semiconductor wafer W.

At step 1412, when only one of the flags F1, F2 and F3 is “1”, i.e., when the semiconductor wafer is pneumatically sucked by only one of the suction ports 33A, 33B and 33C, the control proceeds from step 1412 to step 1417, in which the upward movement of the lower pneumatic sucker arm 3 is stopped. Then, the control returns to step 1107 of the wafer-unloading routine of FIG. 11.

Namely, when the semiconductor wafer W is pneumatically sucked by only one of the suction ports 33A, 33B and 33C, the second pressure-sensor monitoring routine of FIG. 13 is executed so that the semiconductor wafer W is held by the sucker portion 42 of the upper pneumatic sucker arm 4, whereby it is possible to ensure a stable holding of the semiconductor wafer W by both the lower and upper pneumatic sucker arms 3 and 4.

On the other hand, at step 1413, when the given time has been elapsed without any one of the digital signals DS_{55A}, DS_{55B} and DS_{55C} being equal to or smaller than the low pressure data LP, i.e., without the semiconductor wafer W being pneumatically sucked by any one of the suction ports 33A, 33B and 33C (see: FIG. 8C), the control proceeds from step 1413 to step 1419, in which an error message is displayed on the display unit (not shown) connected to the microcomputer 71 (see: FIG. 10). Then, the routine of FIG. 14 is completed by step 1420.

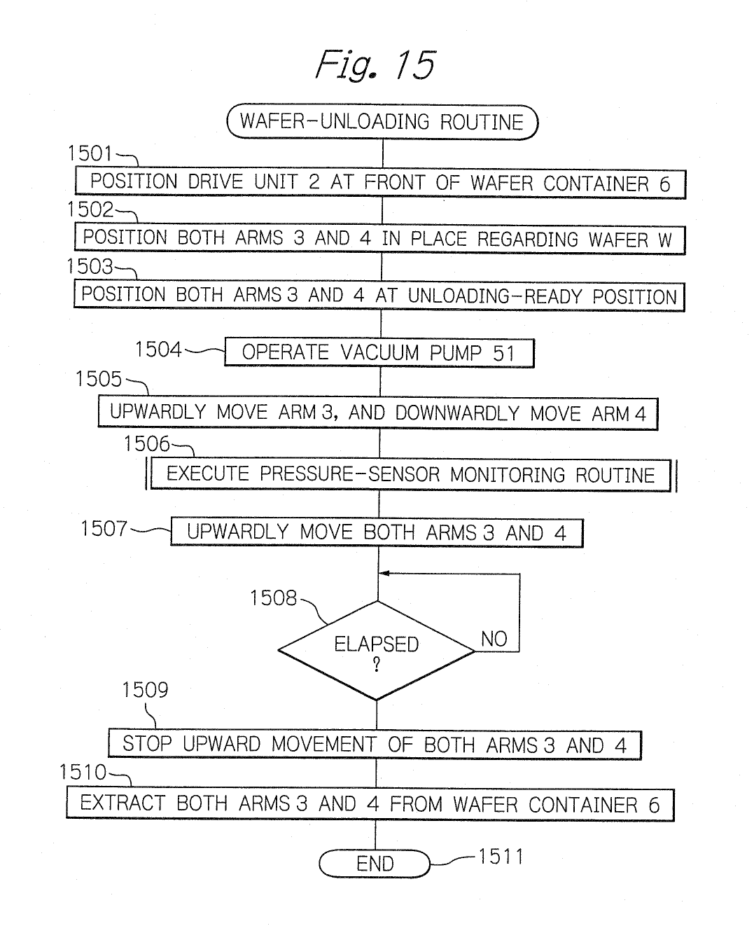

FIG. 15 shows another flowchart of the wafer-unloading routine executed in the microcomputer 71 of FIG. 10.

At step 1501, the drive unit 2 (see: FIG. 4) is positioned at the front of the wafer container 6 (see; Fig. FIGS. 7A and 7B) by driving the electric motors 14A and 15A of the ball/screw mechanisms 14 and 15 (see: FIG. 10), with a space between the lower and upper pneumatic sucker arms 3 and 4 being set into the predetermined space PS (see: FIG. 8A).

At step 1502, both the lower and upper pneumatic sucker arms 3 and 4 are vertically and synchronously moved by driving the electric motors 24A and 25A of the rack/pinion mechanisms 24 and 25 (see: FIG. 10) to be positioned in place with respect to one of the semiconductor wafers W so that the semiconductor wafer W concerned is brought to the mid point between the lower and upper pneumatic sucker arms 3 and 4.

At step 1503, the drive unit 2 is moved in the Y-direction (see: FIG. 4) by driving the electric motor 15A of the ball/screw mechanism 15 (see: FIG. 10) so that both the sucker portions 32 and 42 of the lower and upper pneumatic sucker arms 3 and 4 are entered into the internal of the wafer container 6 by the predetermined length PL (see: FIG. 8A), with the semiconductor wafer W being intervened between the lower and upper pneumatic sucker arms 3 and 4. Thus, both the lower and upper pneumatic sucker arms 3 and 4 are positioned at the unloading-ready position (see: FIG. 8A). At this time, the sucker portion 32 of the lower pneumatic sucker arm 3 is spaced apart from the back surface of the semiconductor wafer W by the predetermined distance PD1 (see: FIG. 8A), and the sucker portion 42 of the upper pneumatic sucker arm 4 is spaced apart from the front surface of the semiconductor wafer W by a smaller distance than the predetermined distance PD1.

At step 1504, the vacuum pump 51 (see: FIGS. 4 and 10) is operated by driving the electric motor 51A thereof. Then, at step 1505, the lower pneumatic sucker arm 3 is upwardly moved by driving the electric motor 24A of the rack/pinion mechanism 24 (see: FIG. 10), and the upper pneumatic sucker arm 4 is downwardly moved by driving the electric motor 25A of the rack/pinion mechanism 25 (see: FIG. 10). Namely, the upward movement of the lower pneumatic sucker arm 3 and the downward movement of the upper pneumatic sucker arm 4 are simultaneously carried out.

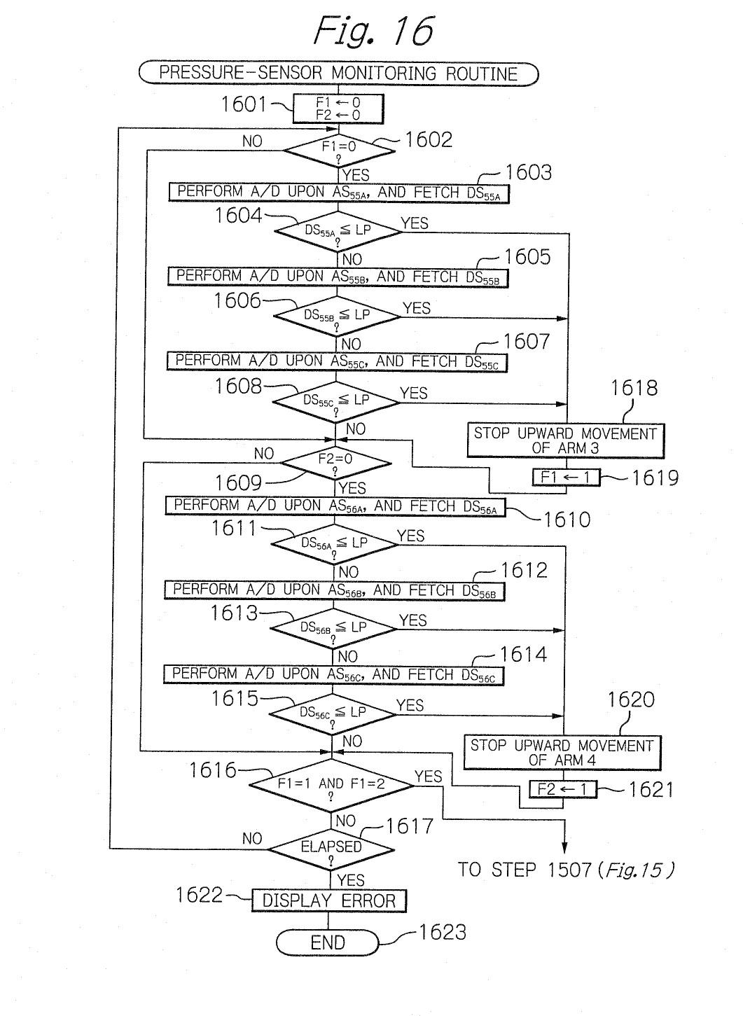

At step 1506, a pressure-sensor monitoring routine is executed to determine whether the semiconductor wafer W has been pneumatically sucked by any one of the suction ports 33A, 33B and 33C of the sucker portion 32 of the lower pneumatic sucker arm 3 and by any one of the suction ports 43A, 43B and 43C of the sucker portion 42 of the lower pneumatic sucker arm 4. When it is confirmed that the semiconductor wafer W has been pneumatically sucked by any one of the suction ports 33A, 33B and 33C, the upward movement of the lower pneumatic sucker arm 3 is stopped. Also, when it is confirmed that the semiconductor wafer W has been pneumatically sucked by any one of the suction ports 43A, 43B and 43C, the downward movement of the upper pneumatic sucker arm 4 is stopped. Note that the pressure-sensor monitoring routine will be explained in detail with reference to FIG. 16.

At step 1507, both the lower and upper pneumatic sucker arms 3 and 4 carrying the sucked semiconductor wafer W are upwardly moved by synchronously driving both the electric motors 24A and 25B of the rack/pinion mechanisms 24 and 25.

At step 1508, it is monitored whether a given time has elapsed. Namely, it is monitored whether the diametrical side edge areas of the semiconductor wafer W have been floated in the opposite side grooves, defined by the two pairs of rib-like side members 62B and 62C of the corresponding U-shaped shelf 62 (FIG. 8C), due to the upward movement of both the lower and upper pneumatic sucker arms 3 and 4.

At step 1508, when it is confirmed that the given time has elapsed, the control proceeds to step 1509 in which the upward movement of both the lower and upper pneumatic sucker arms 3 and 4 is stopped.

At step 1510, the drive unit 2 (see: FIG. 4) is moved in the Y-direction by driving the electric motor 14A of the ball/screw mechanism 14 so that both the lower and upper pneumatic sucker arms 3 and 4 carrying the sucked semiconductor wafer W are extracted from the wafer container 6, resulting in completion of the unloading of the semiconductor wafer W from the wafer container 6. Then, the routine of FIG. 15 is completed by step 1511.

FIG. 16 shows a detailed flowchart of the pressure-sensor monitoring routine executed at step 1506 of FIG. 15.

First, at step 1601, flags F1 and F2 are initialized to be “0”. Note that the flag F1 indicates whether the semiconductor wafer W is pneumatically sucked by any one of the suction ports 33A, 33B and 33C of the sucker portion 32 of the lower pneumatic sucker arm 3, and that the flag F2 indicates whether the semiconductor wafer W is pneumatically sucked by any one of the suction ports 43A, 43B and 43C of the sucker portion 42 of the upper pneumatic sucker arm 4.

Next, at step 1602, it is determined whether the flag F1 is “0” or “1,”. At the initial stage, since F1=0, the control proceeds to step 1603, in which the microcomputer 71 (see: FIG. 10) generates a selection signal SS for the pressure sensor 55A, so that the A/D converter 73 performs an A/D conversion upon an analog signal AS_{55A} of the pressure sensor 55A to thereby obtain a digital signal DS_{55A} representing an internal pressure in the rigid pipe 53A (see: FIG. 4).

Next, at step 1604, it is determined whether the digital signal DS_{55A} is equal to or smaller than the low pressure data LP read from the ROM of the system controller 71 (see: FIG. 10). If DS_{55A}>LP, the control proceeds to step 1605.

Next, at step 1605, the microcomputer 71 (see: FIG. 10) generates a selection signal SS for the pressure sensor 55B, so that the A/D converter 73 performs an A/D conversion upon an analog signal AS_{55B} of the pressure sensor 55B to thereby obtain a digital signal DS_{55B} representing an internal pressure in the rigid pipe 53B (see: FIG. 4). Then, the digital signal DS_{55B} is fetched by the microcomputer 71.

Next, at step 1606, it is determined whether the digital signal DS_{55B} is equal to or smaller than the low pressure data LP. If DS_{55B}>LP, the control proceeds to step 1607.

Next, at step 1607, the microcomputer 71 (see: FIG. 10) generates a selection signal SS for the pressure sensor 55C, so that the A/D converter 73 performs an A/D conversion upon an analog signal AS_{55C} of the pressure sensor 55C to thereby obtain a digital signal DS_{55C} representing an internal pressure in the rigid pipe 53C (see: FIG. 4). Then, the digital signal DS_{55C} is fetched by the microcomputer 71.

Next, at step 1608, it is determined whether the digital signal DS_{55C} is equal to or smaller than the low pressure data LP. If DS_{55C}>LP, the control proceeds to step 1609.

Next, at step 1609, it is determined whether the flag F2 is “0” or “1”. At the initial stage, since F2=0, the control proceeds to step 1610, in which the microcomputer 71 (see: FIG. 10) generates a selection signal SS for the pressure sensor 56A, so that the A/D converter 73 performs an A/D conversion upon an analog signal AS_{56A} of the pressure sensor 56A to thereby obtain a digital signal DS_{56A} representing an internal pressure in the rigid pipe 54A (see: FIG. 4). Then, the digital signal DS_{56A} is fetched by the microcomputer 71.

Next, at step 1611, it is determined whether the digital signal DS_{56A} is equal to or smaller than the low pressure data LP read from the ROM of the system controller 71 (see: FIG. 10). If DS_{56A}>LP, the control proceeds to step 1612.

Next, at step 1612, the microcomputer 71 (see: FIG. 10) generates a selection signal SS for the pressure sensor 56B, so that the A/D converter 73 performs an A/D conversion upon an analog signal AS_{56B} of the pressure sensor 56B to thereby obtain a digital signal DS_{56B} representing an internal pressure in the rigid pipe 54B (see: FIG. 4). Then, the digital signal DS_{56B} is fetched by the microcomputer 71.

Next, at step 1613, it is determined whether the digital signal DS_{56B} is equal to or smaller than the low pressure data LP. If DS_{56B}>LP, the control proceeds to step 1614.

Next, at step 1614, the microcomputer 71 (see: FIG. 10) generates a selection signal SS for the pressure sensor 56C, so that the A/D converter 73 performs an A/D conversion upon an analog signal AS_{56C} of the pressure sensor 56C to thereby obtain a digital signal DS_{56C} representing an internal pressure in the rigid pipe 54C (see: FIG. 4). Then, the digital signal DS_{56C} is fetched by the microcomputer 71.

Next, at step 1615, it is determined whether the digital signal DS_{56C} is equal to or smaller than the low pressure data LP. If DS_{56C}>LP, the control proceeds to step 1616.

Next, at step 1616, it is monitored whether both the flags F1 and F2 are made to be “1”. At the initial stage, since F1=1 and F2=1, the control proceeds to step 1517.

Next, at step 1617, it is monitored whether a given time has elapsed. Note that this given time is defined as an adequate time for the lower and upper pneumatic sucker arms 3 and 4 to reach the respective back and front surfaces of the semiconductor wafer W. When it is determined that the given time has not elapsed, the control returns to step 1602, and the routine comprising steps 1602 to 1607 is repeated until it is determined that any one of the digital signals DS_{55A}, DS_{55B} and DS_{55C} is equal to or smaller than the low pressure data LP at step 1604, 1606 or 1608 or until it is determined that any one of the digital signals DS_{56A}, DS_{56B} and DS_{56C} is equal to or smaller than the low pressure data LP at step 1611, 1613 or 1615.

In particular, at any one of steps 1604, 1606 and 1608, when it is determined that the digital signals DS_{55A}, DS_{55B} or DS_{55C} is equal to or smaller than the low pressure data LP, i.e., when it is determined that the semiconductor wafer W has been pneumatically sucked by any one of the suction ports 33A, 33B and 33C of the sucker portion 32 of the lower pneumatic sucker arm 3, the control proceeds to step 1604, 1606 or 1608 to step 1618, in which the upward movement of the lower pneumatic sucker arm 3 is stopped. Then, at step 1619, the flag F1 is made to be “1”, and the control proceeds to step 1609.

Also, at any one of steps 16011, 1613 and 1615, when it is determined that the digital signals DS_{56A}, DS_{56B} or DS_{56C} is equal to or smaller than the low pressure data LP, i.e., when it is determined that the semiconductor wafer W has been pneumatically sucked by any one of the suction ports 43A, 43B and 43C of the sucker portion 42 of the upper pneumatic sucker arm 4, the control proceeds to step 16011, 1613 or 1615 to step 1620, in which the downward movement of the upper pneumatic sucker arm 4 is stopped. Then, at step 1621, the flag F2 is made to be “1”, and the control proceeds to step 1616.

At step 1616, when it is determined that only one of the flags F1 and F2 has been made to be “1”, the control returns to step 1602. If only flag F1 is “1”, the routine comprising steps 1602, 1609 to 1617, and 1620 and 1621 is repeated. Also, if only flag F2 is “1”, the routine comprising steps 1602 to 1609, and 1616 to 1619 is repeated.

Also, at step 1616, when it is determined that both the flags F1 and F2 have been made to be “1”, the control returns from step 1616 to step 1507 of the wafer-unloading routine of FIG. 15.

On the other hand, at step 1617, when the given time has elapsed without both the flags F1 and F2 being made to be “1”, i.e., without the semiconductor wafer W being pneumatically sucked and held by both the lower and upper pneumatic sucker arms 3 and 4, the control proceeds from step 1617 to step 1622, in which an error message is displayed on the display unit (not shown) connected to the system controller 71 (see: FIG. 10). Then, the control returns to the main routine of the substrate transfer apparatus of FIG. 4.

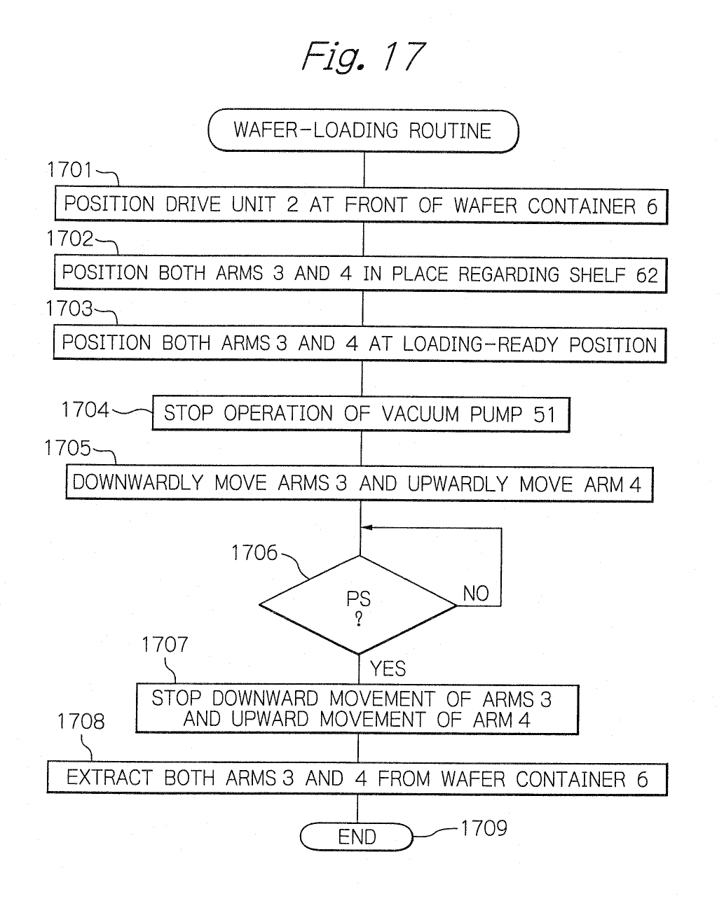

FIG. 17 shows a flowchart of a wafer-loading routine executed in the microcomputer 71 of FIG. 10.

Note, when the wafer-loading routine is executed, the semiconductor wafer W is pneumatically held by either only the lower pneumatic sucker arm 3 or both the lower and upper pneumatic sucker arms 3 and 4.

At step 1701, the drive unit 2 (see: FIG. 4) is positioned at the front of the wafer container 6 (see; Fig. FIGS. 7A and 7B) by driving the electric motors 14A and 17A of the ball/screw mechanisms 14 and 15 (see: FIG. 10).

At step 1702, both the lower and upper pneumatic sucker arms 3 and 4 are vertically and synchronously moved by driving the electric motors 24A and 25A of the rack/pinion mechanisms 24 and 25 (see: FIG. 10) to be positioned in place with respect to one of the U-shaped shelves 62 of the wafer container 6 (see: FIGS. 7A and 7B) so that the semiconductor wafer W concerned is brought to the mid point of both the grooves defined by the two pairs of rib-like side members 62B (see: FIGS. 7A and 7B) and 62C (see: FIG. 7B) of the U-shaped shelf concerned. Note that, of course, the U-shaped shelf 62 concerned contains no semiconductor wafer W.

At step 1703, the drive unit 2 is moved in the Y-direction (see: FIG. 4) by driving the electric motor 17A of the ball/screw mechanism 17 (see: FIG. 10) so that both the sucker portions 32 and 42 of the lower and upper pneumatic sucker arms 3 and 4 are entered into the internal of the wafer container 6 by the predetermined length PL (see: FIG. 8A), whereby both the lower and upper pneumatic sucker arms 3 and 4 are positioned at a loading-ready position.

At step 1704, the operation of the vacuum pump 51 (see: FIGS. 4 and 10) is stopped to thereby release the pneumatic holding of the semiconductor wafer W by both the sucker portions 32 and 42 of the lower and upper pneumatic sucker arms 3 and 4.

At step 1705, the lower pneumatic sucker arm 3 is downwardly moved by driving the electric motor 24A of the rack/pinion mechanism 24 (see: FIG. 10), and the upper pneumatic sucker arm 4 is upwardly moved by the electric motor 25A of the rack/pinion mechanism 25 (see: FIG. 10).

At step 1706, it is monitored whether the lower and upper pneumatic sucker arms 3 and 4 are spaced apart from each other by the predetermined space PS (see: FIG. 8A).

At the step 1706, when it is confirmed that the lower and upper pneumatic sucker arms 3 and 4 are spaced apart from each other by the predetermined space PS, the control proceeds to step 1707, in which the downward movement of the lower pneumatic sucker arm 3 and the upward movement of the upper pneumatic sucker arm 4 are stopped.

At step 1707, the drive unit 2 (see: FIG. 4) is moved in the Y-direction by driving the electric motor 14A of the ball/screw mechanism 14 so that both the lower and upper pneumatic sucker arms 3 and 4 carrying the semiconductor wafer W are extracted from the wafer container 6, resulting in completion of the loading of the semiconductor wafer W in the wafer container 6.

### Second Embodiment

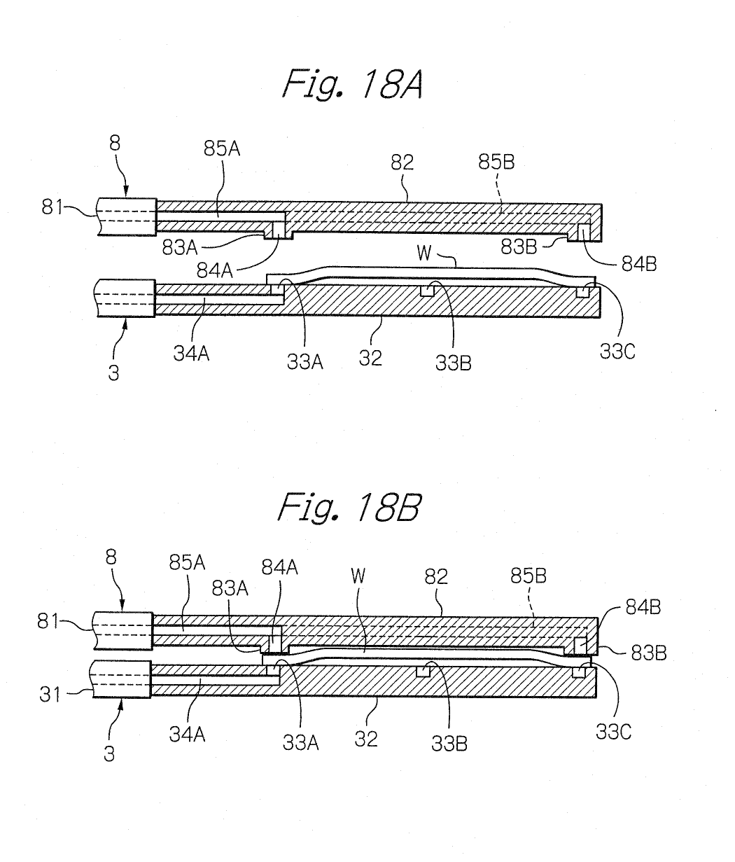

With reference to FIGS. 18A and 18B which are partially-enlarged views corresponding to FIGS. 8B and 8C, respectively, in a second embodiment of the substrate transfer apparatus according to the present invention, an upper pneumatic sucker arm 8 is substituted for the upper pneumatic sucker arm 4.

First, referring to FIG. 18A, the upper pneumatic sucker arm 8 includes a base portion 81 securely attached to the top of the movable column 23 (see: FIG. 4), and a sucker portion 82 extending therefrom. Namely, similarly to the upper pneumatic sucker arm 4, the upper pneumatic sucker arm 8 is supported by the movable column 23 in a cantilever manner.

The sucker portion 82 of the upper pneumatic sucker arm 8 has two projections 83A and 83B protruded from the lower face thereof and aligned with each other along a central longitudinal axis of the sucker portion 82, and suction ports 84A and 84B are formed in the respective projections 83A and 83B.

Also, the upper pneumatic sucker arm 8 has air passages 85A and 85B formed in both the base portion 81 and the sucker portion 82 so as to be in communication with the respective suction ports 84A and 84B, and the air passages 85A and 85B are in communication with the flexible conduits 58A and 58B (see: FIG. 4). Note, in the second embodiment, the rigid pipe 54C, the pressure sensor 56C and the flexible conduit 58C are eliminated.

As shown in FIG. 18A, the semiconductor wafer W is warped so that the front and back surfaces of the semiconductor wafer W are defined as respective convex and concave surfaces, and the back surface of the semiconductor wafer W is pneumatically sucked by the suction ports 33A and 33C.

As shown in FIG. 18B, when the upper pneumatic sucker arm 8 is downwardly moved, it is possible to pneumatically suck the front surface of the semiconductor wafer W by the suction ports 84A and 84B without contacting the front surface of the semiconductor wafer W with the lower face of the sucker portion 82 of the upper pneumatic sucker arm 8 because the projections 83A and 83B serve as spacers when they are abutted against the upper face of the sucker portion 32 of the lower pneumatic sucker arm 3, whereby some semiconductor devices on the front surface of the semiconductor wafer W can be protected from being mechanically damaged.

Preferably, the projections or spacers 84A and 83B have a height which defines a sufficient space between the sucker portions 32 and 82 of the lower and upper pneumatic sucker arms 3 and 8 to receive a maximum warped semiconductor wafer W, without the front surface of the maximum warped semiconductor wafer W coming in contact with the lower face of the sucker portion 82 of the upper pneumatic sucker arm 8.

Finally, it will be understood by those skilled in the art that the foregoing description is of preferred embodiments of the apparatus, and that various changes and modifications may be made to the present invention without departing from the spirit and scope thereof.

1. A substrate transfer apparatus that pneumatically holds and transfers a substrate having first and second surfaces, which apparatus comprises:
a first pneumatic sucker arm having at least two first suction ports for pneumatically sucking the first surface of said substrate;
a first drive mechanism that vertically moves said first pneumatic sucker arm toward the first surface of said substrate, with said at least two first suction ports being directed to the first surface of said substrate;
a plurality of first pressure sensors that detect respective sucking pressures generated in said at least two first suction ports;
a second pneumatic sucker arm having at least two second suction ports for pneumatically sucking the second surface of said substrate;
a second drive mechanism that vertically moves said second pneumatic sucker arm toward the second surface of said substrate, with said at least two second suction ports being directed to the second surface of said substrate;
a plurality of second pressure sensors that detect respective sucking pressures generated in said at least two second suction ports; and
a control circuit controls the vertical movement of said first pneumatic sucker arm in accordance with the respective sucking pressures detected by said first pressure sensors and the vertical movement of said second pneumatic sucker arm in accordance with the respective sucking pressures detected by said second pressure sensors.

2. The substrate transfer apparatus as set forth in claim 1, wherein said control circuit stops the vertical movement of said first pneumatic sucker arm when a sucking pressure in any one of said at least two first suction ports is detected as a predetermined low pressure by a corresponding one of said first pressure sensors, and wherein said control circuit stops the vertical movement of said second pneumatic sucker arm when a sucking pressure in any one of said at least two second suction ports is detected as a predetermined low pressure by a corresponding one of said second pressure sensors.

3. The substrate transfer apparatus as set forth in claim 1, wherein said control circuit stops a movement of said second pneumatic sucker arm when the sucking pressures in said at least two first suction ports are lowered to a predetermined low pressure.

4. The substrate transfer apparatus as set forth in claim 1, wherein said substrate is defined as a semiconductor wafer, said at least two first suction ports being spaced apart from each other so as to be in contact with respective diametrical side edge areas on the first surface of said semiconductor wafer, said at least two second suction ports being spaced apart from each other so as to be in contact with respective diametrical side edge areas on the second surface of said semiconductor wafer.

5. The substrate transfer apparatus as set forth in claim 4, wherein said at least two first suction ports are defined as endmost suction ports, said first pneumatic sucker arm further having an additional first suction port arranged between said endmost first suction ports.

6. The substrate transfer apparatus as set forth in claim 4, wherein said at least two second suction ports are defined as endmost suction ports, said second pneumatic sucker arm further having an additional first suction port arranged between said endmost first suction ports.

7. The substrate transfer apparatus as set forth in claim 1, wherein said substrate is defined as a semiconductor wafer, said second pneumatic sucker arm has two projections, said at least two suction ports being formed in said projections, and being spaced apart from each other so as to be in contact with respective diametrical side edge areas on the second surface of said semiconductor wafer.

8. The substrate transfer apparatus as set forth in claim 7, wherein said projections have a height which defines a sufficient space between said first and second pneumatic sucker arms to receive a maximum warped semiconductor wafer, without the second surface of said maximum warped semiconductor wafer brought into contact with the second pneumatic sucker arm.

9. A method for transferring a substrate having first and second surfaces, which method comprises:
positioning a first pneumatic sucker arm having at least two first suction ports and a second pneumatic sucker arm having at least two second suction ports in place with respect to said substrate, so that said at least two first suction ports and said at least two second suction ports are directed to the respective first and second surfaces of said substrate;
moving said first pneumatic sucker arm toward the first surface of said substrate;
detecting respective first sucking pressures generated in said at least two first suction ports;
stopping the movement of said first pneumatic sucker arm when it is detected that any one of said first sucking pressures is lowered to a predetermined low pressure;
moving said second pneumatic sucker arm toward the second surface of said substrate;
detecting respective second sucking pressures generated in said at least two second suction ports; and
stopping the movement of said second pneumatic sucker arm when it is detected that any one of said second sucking pressures is lowered to said predetermined low pressure.

10. A method for transferring a substrate having first and second surfaces, which method comprises:
positioning a first pneumatic sucker arm having at least two first suction ports and a second pneumatic sucker arm having at least two second suction ports in place with respect to said substrate, so that said at least two first suction ports and said at least two second suction ports are directed to the respective first and second surfaces of said substrate;
moving said first pneumatic sucker arm and said second pneumatic sucker arm toward the first and second surfaces of said substrate, respectively;
detecting respective first sucking pressures generated in said at least two first suction ports and respective second sucking pressures generated in said at least two second suction ports;
stopping the movement of said first pneumatic sucker arm when it is detected that any one of said first sucking pressures is lowered to a predetermined low pressure; and
stopping the movement of said second pneumatic sucker arm when it is detected that any one of said second sucking pressures is lowered to said predetermined low pressure.
